(19) United States
(12) Patent Application Publication
(10) Pub. No.: US 2026/0212911 A1
(43) Pub. Date: Jul. 23, 2026

(54) MEMORY DEVICE AND MEMORY SYSTEM INCLUDING THE SAME

(71) Applicant: Samsung Electronics Co., Ltd., Suwon-si (KR)

(72) Inventors: Soyeong Shin, Suwon-si (KR); Changsoo Yoon, Suwon-si (KR)

(21) Appl. No.: 19/285,773

(22) Filed: Jul. 30, 2025

(30) Foreign Application Priority Data
Jan. 21, 2025 (KR) 10-2025-0008899

(51) Int. Cl. G11C 11/4091; G11C 11/4076; G11C 11/4093

(52) U.S. Cl. CPC G11C 11/4091; G11C 11/4076; G11C 11/4093

(57) ABSTRACT

A memory device includes a buffer configured to compare a data signal to a reference voltage and generate an amplified signal, a summer configured to generate a summer output signal based on the amplified signal, and a sampler including a sampling circuit configured to sample the summer output signal based on a clock signal to generate a sampling signal, and a first equalization circuit structure connected to the sampling circuit and configured to equalize the sampling signal based on a feedback sampling signal sampled prior to the sampling signal. The first equalization circuit structure includes a first transistor into which the feedback sampling signal is input, a second transistor structure between the first transistor and the sampling circuit and into which a bias voltage associated with an equalization coefficient is input, and a third transistor structure disposed the first transistor and the sampling circuit.

### CROSS-REFERENCE TO RELATED APPLICATION

This application claims priority under 35 U.S.C. § 119 to Korean Patent Application No. 10-2025-0008899, filed in the Korean Intellectual Property Office on Jan. 21, 2025, the entire contents of which are hereby incorporated by reference.

### BACKGROUND

A semiconductor memory device may be classified as a volatile memory device or a nonvolatile memory device depending on whether stored data are lost when the power supply is interrupted. The volatile memory device may lose stored data when the power supply is cut off, and the nonvolatile memory device may preserve stored data even when the power supply is interrupted.

### SUMMARY

Recently, as performance of semiconductor memory devices has improved, high communication speeds (or interface speeds) between a memory controller and a semiconductor memory device are desired, and the increased communication speed may affect performance of a receiver included in the semiconductor memory device. For example, due to various factors such as skin effect, dielectric loss, etc., a data signal delivered through a channel may include noise such as intersymbol interference (ISI), which may degrade quality of a high-speed data signal.

In addition, in a high-speed data transmission environment, a voltage offset caused by device mismatch or circuit nonlinearity may degrade signal accuracy. Such a voltage offset may cause a difference between a reference voltage of a data signal and an actual signal voltage in the input path of the receiver, which may worsen intersymbol interference (ISI) and reduce accuracy in signal determination.

The disclosed technology relates to memory devices and memory systems including the same.

The present disclosure relates to a memory device and a memory system including the same, for resolving the aforementioned issues.

Problems to be solved by aspects of some implementations of the present disclosure are not limited to those described above, and other problems not mentioned will be clearly understood by those of ordinary skill in the art from the following description.

According to an implementation of the present disclosure, a memory device may include a buffer configured to compare a data signal to a reference voltage and generate an amplified signal, a summer configured to generate a summer output signal based on the amplified signal, and a sampler including a sampling circuit configured to sample the summer output signal based on a clock signal and generate a sampling signal, and a first equalization circuit structure connected to the sampling circuit and configured to equalize the sampling signal based on a feedback sampling signal sampled prior to the sampling signal. The first equalization circuit structure may include a first transistor into which the feedback sampling signal is input, a second transistor disposed between the first transistor and the sampling circuit and into which a bias voltage associated with an equalization coefficient is input, and a third transistor disposed between the first transistor and the sampling circuit and into which an offset compensation signal for the sampler is input.

According to an implementation of the present disclosure, a memory device may include a receive circuit configured to process a data signal received from a memory controller and generate output data, and a control logic circuit configured to control the receive circuit and generate an offset compensation signal for the receive circuit. The receive circuit may include a buffer configured to compare the data signal to a reference voltage and generate an amplified signal, a summer configured to generate a summer output signal based on the amplified signal, and a sampler including a sampling circuit configured to sample the summer output signal based on a clock signal and generate a sampling signal, and a first equalization circuit structure connected to the sampling circuit and configured to equalize the sampling signal based on a feedback sampling signal sampled prior to the sampling signal. The first equalization circuit structure may include a first transistor into which the feedback sampling signal is input, a second transistor disposed between the first transistor and the sampling circuit and into which a bias voltage associated with an equalization coefficient is input, and a third transistor disposed between the first transistor and the sampling circuit and into which an offset compensation signal for the sampler is input.

According to an implementation of the present disclosure, a memory system may include a memory device and a memory controller configured to write data to the memory device or read out data stored in the memory device. The memory device may include a receive circuit configured to process a data signal received from the memory controller and generate output data, and a control logic circuit configured to control the receive circuit and generate an offset compensation signal for the receive circuit. The receive circuit may include a buffer configured to compare the data signal to a reference voltage and generate an amplified signal, a summer configured to generate a summer output signal based on the amplified signal, and a sampler including a sampling circuit configured to sample the summer output signal based on a clock signal and generate a sampling signal, and a first equalization circuit structure connected to the sampling circuit and configured to equalize the sampling signal based on a feedback sampling signal sampled prior to the sampling signal. The first equalization circuit structure may include a first transistor into which the feedback sampling signal is input, a second transistor disposed between the first transistor and the sampling circuit and into which a bias voltage associated with an equalization coefficient is input, and a third transistor disposed between the first transistor and the sampling circuit and into which an offset compensation signal for the sampler is input.

According to various implementations of the present disclosure, the receive circuit may perform a calibration operation for voltage offsets in each feedback path of an equalization circuit having various feedback paths. Through this, a voltage offset may be effectively removed or reduced, increasing a data sampling margin and improving accuracy and reliability in data determination.

According to various implementations of the present disclosure, even in a high-speed data transmission environment, the influence of intersymbol interference and noise may be reduced, enabling stable signal processing.

According to various implementations of the present disclosure, a voltage offset due to mismatch among a plurality of elements included in the receive circuit may be effectively calibrated, thereby improving data signal accuracy and reliability.

According to various implementations of the present disclosure, a current flow path of a feedback signal may be set more succinctly. Through such a configuration, signal delay occurring in the feedback path may be reduced, and feedback time may be effectively reduced.

According to various implementations of the present disclosure, an equalization coefficient applied to the equalization circuit may remain stable without being affected by variations of a supply voltage (VDD).

Effects obtainable through the present disclosure are not limited to the aforementioned. Other technical effects not mentioned will be clearly understood by those of ordinary skill in the art from the following description.

### BRIEF DESCRIPTION OF THE DRAWINGS

FIG. 1 is a block diagram for explaining a transmitter-receiver system according to some implementations of the present disclosure.

FIG. 2 is a diagram for explaining the effect of a voltage offset.

FIG. 3 is a diagram for explaining a receive circuit according to some implementations of the present disclosure.

FIG. 4 is a diagram for explaining a summer according to some implementations of the present disclosure.

FIG. 5 is a diagram for explaining a sampler according to some implementations of the present disclosure.

FIG. 6 is a diagram for explaining a bias voltage generation circuit according to some implementations of the present disclosure.

FIG. 7 is a diagram for explaining a sampler according to some implementations of the present disclosure.

FIG. 8 is a diagram for explaining a control logic circuit according to some implementations of the present disclosure.

FIG. 9 is a diagram for explaining a first control block according to some implementations of the present disclosure.

FIG. 10 is a diagram for explaining a second control block according to some implementations of the present disclosure.

FIG. 11 is a diagram for explaining a third control block according to some implementations of the present disclosure.

FIG. 12 is a timing diagram showing an initial operation of a receiver according to some implementations of the present disclosure.

FIG. 13 is a diagram for explaining an offset calibration operation according to some implementations of the present disclosure.

FIG. 14 is a diagram for explaining an offset calibration operation according to some implementations of the present disclosure.

FIG. 15 is a diagram for explaining an offset calibration operation according to some implementations of the present disclosure.

FIG. 16 is a block diagram for explaining a memory system according to some implementations of the present disclosure.

FIG. 17 is a block diagram illustrating an example of an electronic device having a receive circuit according to some implementations of the present disclosure.

### DETAILED DESCRIPTION

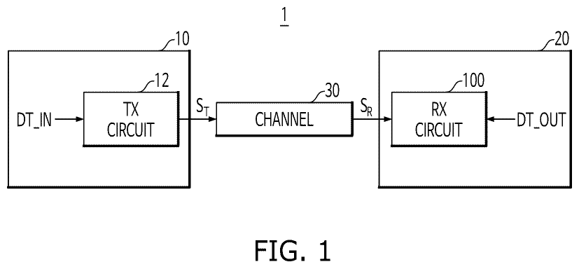

Hereinafter, various implementations of the present disclosure will be described with reference to FIGS. 1-17. Identical reference numerals throughout the specification may denote identical components.

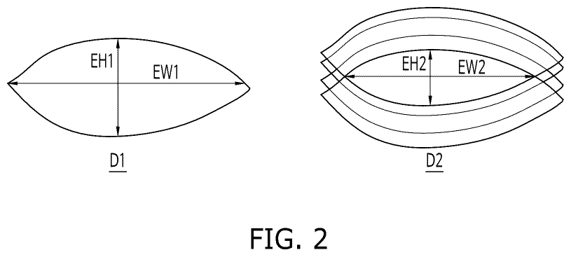

FIG. 1 is a block diagram for explaining a transmitter-receiver system according to some implementations of the present disclosure. FIG. 2 is a diagram for explaining the effect of a voltage offset.

Referring to FIG. 1, a transmitter-receiver system 1 according to some implementations of the present disclosure may include a transmitter 10 and a receiver 20 configured to communicate with each other through a channel 30.

The transmitter 10 may include a transmit circuit 12. The transmit circuit 12 may receive transmit data DT_IN to be delivered and output a transmit signal ST based on the transmit data DT_IN. The transmit circuit 12 may deliver the transmit signal ST to the receiver 20 through the channel 30. As the transmit signal ST passes through the channel 30, the transmit signal ST may become a receive signal SR. In some implementations, the transmit circuit 12 may perform a signal equalization operation to compensate for channel loss.

The receiver 20 may include a receive circuit 100. The receive circuit 100 may receive the receive signal SR through the channel 30 and output receive data DT_OUT based on the receive signal SR. In an exemplary implementation, as the transmit signal ST passes through the channel 30, the transmit signal ST may be distorted by a response characteristic of the channel 30 or noise. Accordingly, the receive circuit 100 may receive the receive signal SR distorted by the response characteristic of the channel 30 or noise. In other words, the receive signal SR may be a signal in which the response characteristic or noise of the channel 30 is reflected in the transmit signal ST.

In some implementations, the receiver 20 may be implemented as a memory device, and the transmitter 10 may be implemented as a memory controller or a host device that controls the memory device. A detailed description of this implementation will be provided below.

In an exemplary implementation, if the transmitter 10 ideally operates so that intersymbol interference (ISI) is properly removed and the channel 30 has no noise, the original transmit data DT_IN may be normally determined through the receive signal SR. However, due to various external factors, the transmitter 10 may not operate ideally, and noise may be introduced into the channel 30, so the receive signal SR may fail to properly determine the original transmit Data DT_IN.

In addition, a voltage offset may occur due to subtle mismatch among the constituent elements of the receive circuit 100. For example, the receive circuit 100 may include a plurality of elements, some of which may be designed to form pairs. However, due to slight differences that occur in the manufacturing process or aging during use, electrical characteristic differences may occur between paired elements, and such characteristic differences may cause a voltage offset. When the receive circuit 100 has an offset, RLM (Ratio of Level separation Mismatch) or sampling margin in an eye diagram of the output signal may be adversely affected.

Furthermore, as the signal path of the receive circuit 100 becomes more varied and complex, such a voltage offset may become more severe. In particular, when voltage offsets arising in multiple paths overlap or interact, signal quality and data determination accuracy may deteriorate.

Specifically, referring to FIG. 2, a first diagram D1 shows an example of an eye diagram of a data signal output from the receive circuit 100 in an ideal case in which no voltage offset occurs, and a second diagram D2 shows an example of an eye diagram of a data signal output from the receive circuit 100 in a case in which a voltage offset occurs. Although not shown, the horizontal axis of each graph may represent time, and the vertical axis may represent voltage levels. For brevity, FIG. 2 shows an eye diagram for 1 UI (unit interval).

Referring to the first diagram D1, when no voltage offset occurs, it can be confirmed that a first eye width EW1 and a first eye height EH1 of the output signal are sufficiently secured. In this case, the reference point for determining whether the data signal is 0 or 1 is stably maintained, so the accuracy of signal determination is high, and susceptibility to noise is low, ensuring data transmission reliability.

Referring to the second diagram D2, when a voltage offset occurs, it can be confirmed that a second eye width EW2 and a second eye height EH2 of the output signal are smaller than the first eye width EW1 and the first eye height EH1 in the first diagram D1. Also, as the data signal path becomes more varied, voltage offsets may occur due to mismatches between paths and subtle mismatches between elements, which may cause fluctuations in the reference point. Consequently, the eye width or eye height may decrease, lowering signal determination accuracy. In particular, such a voltage offset may overlap across different paths, cumulatively affecting the signal in a high-speed data transmission environment, exacerbating intersymbol interference and reducing signal determination accuracy.

According to various implementations of the present disclosure, the receive circuit 100 may perform a calibration operation for the voltage offset arising in each feedback path of an equalization circuit having various feedback paths. Through this, the voltage offset may be effectively removed or reduced, the sampling margin may be increased, and the accuracy and reliability of data determination may be improved. Through such a configuration, stable signal processing may be achieved even in a high-speed data transmission environment.

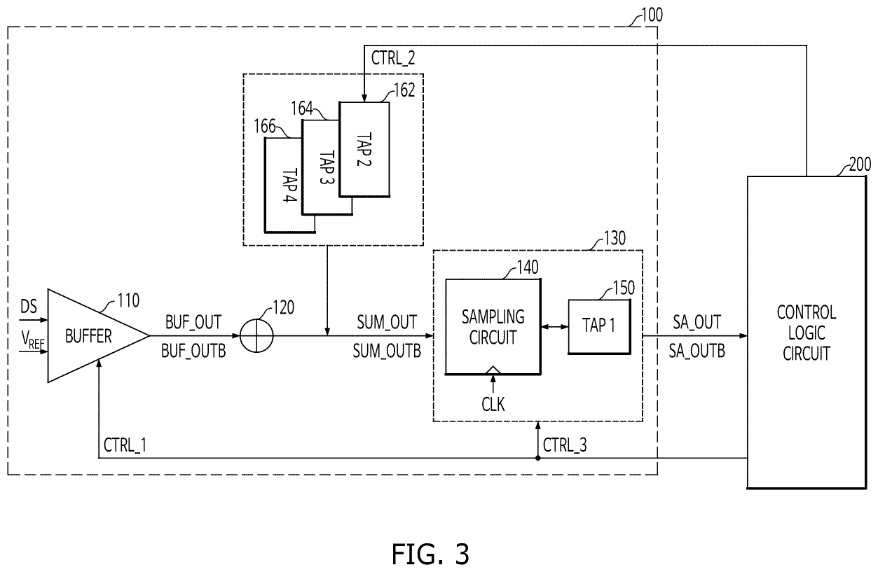

FIG. 3 is a diagram for explaining a receive circuit according to some implementations of the present disclosure.

Referring to FIG. 3, the receive circuit 100 may include a buffer 110, a summer 120, and a sampler 130. The receive circuit 100 may also be connected to a control logic circuit 200.

The buffer 110 may receive a data signal DS and a reference voltage VREF to process an input signal. The buffer 110 may generate a differential signal based on a voltage difference between the data signal DS and the reference voltage VREF. The buffer 110 may also amplify the generated differential signal to generate amplified signals BUF_OUT, BUF_OUTB. For example, the amplified signal BUF_OUT may have the same phase as the data signal DS, and the amplified signal BUF_OUTB may have a phase opposite to that of the data signal DS. The generated amplified signals BUF_OUT, BUF_OUTB may be provided to the summer 120.

In the following description, the description of a certain signal may be understood as including differential signals. For example, the amplified signals BUF_OUT, BUF_OUTB may be understood as a concept collectively referring to both the amplified signal BUF_OUT and a differential amplified signal BUF_OUTB having a phase opposite to the amplified signal BUF_OUT. Also, if a certain signal is described as having a first logic level (e.g., high), it may be understood that the differential signal of that certain signal has a second logic level (e.g., low). For example, if the amplified signal BUF_OUT has a first logic level, it may be understood that, at the same time, the differential amplified signal BUF_OUTB has a second logic level. The same logic applies not only when the specific signal is a digital signal but also when it is an analog signal.

In some implementations, the buffer 110 may receive a first control signal CTRL_1 from the control logic circuit 200. The control logic circuit 200 may transmit the first control signal CTRL_1 to the buffer 110 in order to perform an offset calibration operation. The buffer 110 may, in response to receiving the first control signal CTRL_1, operate so as to output a supply voltage as the amplified signals BUF_OUT, BUF_OUTB. In other words, during the offset calibration operation, the amplified signals BUF_OUT, BUF_OUTB output from the buffer may be held at the supply voltage.

The summer 120 may receive the amplified signals BUF_OUT, BUF_OUTB output from the buffer 110. The summer 120 may generate summer output signals SUM_OUT, SUM_OUTB based on the amplified signals BUF_OUT, BUF_OUTB. In an exemplary implementation, the summer 120 may perform a continuous-time linear equalization (CTLE) operation based on the amplified signals BUF_OUT, BUF_OUTB to generate the summer output signals SUM_OUT, SUM_OUTB.

Additionally, the summer output signals SUM_OUT, SUM_OUTB may be signals in which equalization coefficients are reflected by at least one of a plurality of equalization circuits, for example, a second equalization circuit structure 162, a third equalization circuit structure 164, or a fourth equalization circuit structure 166, from the signals output by the summer 120. The second equalization circuit structure 162, the third equalization circuit structure 164, and the fourth equalization circuit structure 166 may each have various equalization coefficient values set to effectively remove intersymbol interference that may occur in an input signal. Depending on the implementation, the second equalization circuit structure 162, the third equalization circuit structure 164, and the fourth equalization circuit structure 166 may be respectively referred to as a second tap, a third tap, and a fourth tap.

In some implementations, the second equalization circuit structure 162 may receive a second control signal CTRL_2 from the control logic circuit 200. In order to perform an offset calibration operation, the control logic circuit 200 may transmit the second control signal CTRL_2 to the second equalization circuit structure 162. In response to receiving the second control signal CTRL_2, the second equalization circuit structure 162 may operate so as to set the summer output signals SUM_OUT, SUM_OUTB from the summer 120 to certain values.

For example, in response to receiving the second control signal CTRL_2, the second equalization circuit structure 162 may operate so as to output the summer output signals SUM_OUT, SUM_OUTB at predetermined values so that a feedback sampling signal fed back from the sampling circuit 140 to a first equalization circuit structure 150 has a first logic level. To do this, the second equalization circuit structure 162 may be connected between the summer 120 and the sampler 130 and may adjust the voltage level of lines on which the summer output signals SUM_OUT, SUM_OUTB are output. In an exemplary implementation, the second equalization circuit structure 162 may branch off a current from a line on which the summer output signal SUM_OUTB is output so as to reduce its voltage level. In contrast, the second equalization circuit structure 162 may not branch off current from the line on which the summer output signal SUM_OUT is output, so the voltage level may be maintained. This may be implemented in such a way that a plurality of elements included in the second equalization circuit structure 162 are controlled by the second control signal CTRL_2. As a result, the summer output signal SUM_OUT may be controlled to have the first logic level, and the summer output signal SUM_OUTB may be controlled to have the second logic level, so that the feedback sampling signal may be set to the first logic level.

Through this, the feedback path in which the offset calibration operation is performed inside the sampler 130 may be clearly set, and a basis may be provided whereby a calibration operation for the voltage offset arising in each feedback path of the sampler 130 having various feedback paths may be performed. A detailed description thereof will be provided below.

The sampler 130 may receive the summer output signals SUM_OUT, SUM_OUTB output from the summer 120. The sampler 130 may generate sampling signals SA_OUT, SA_OUTB based on the summer output signals SUM_OUT, SUM_OUTB. The sampling signals SA_OUT, SA_OUTB may be signals output from the sampling circuit 140, in which equalization coefficients are reflected by the first equalization circuit structure 150. To accomplish this, the sampler 130 may include a sampling circuit 140 configured to sample the summer output signals SUM_OUT, SUM_OUTB based on a clock signal CLK to generate a sampling signal, and the sampler 130 may include the first equalization circuit structure 150 connected to the sampling circuit 140 and configured to equalize the sampling signal based on a feedback sampling signal (or a previous sampling signal) sampled prior to the sampling signal. Here, the feedback sampling signal may be a signal sampled one unit interval (1 UI) before the currently sampled sampling signal.

The sampling circuit 140 may sample the summer output signals SUM_OUT, SUM_OUTB in synchronization with a rising or falling edge of the clock signal CLK and transmit the generated sampling signal to the first equalization circuit structure 150. In some implementations, the sampling circuit 140 may be designed to perform stable signal sampling in a high-speed data transmission environment and may correct in real time a timing change of an input signal to maintain the accuracy of the sampling frequency. Additionally, the sampling circuit 140 may be configured to suppress sampling errors due to jitter of the clock signal CLK. In an exemplary implementation, the sampling circuit 140 may deliver the currently sampled sampling signal to the first equalization circuit structure 150 so that the first equalization circuit structure 150 may equalize a sampling signal to be generated after the currently sampled sampling signal.

The first equalization circuit structure 150 may be configured to compensate for a current sampling signal based on a previously sampled signal. The first equalization circuit structure 150 may apply an equalization coefficient to remove or reduce intersymbol interference of the input signal, compensate for signal distortion, and improve quality of the sampling signals SA_OUT, SA_OUTB. Further, the first equalization circuit structure 150 may minimize signal distortion that may occur during data transmission by performing a compensation operation while simultaneously considering amplitude and phase characteristics of the signal.

In an exemplary implementation, each of the first equalization circuit structure 150, the second equalization circuit structure 162, the third equalization circuit structure 164, and the fourth equalization circuit structure 166 may be implemented as a decision feedback equalizer (DFE). Each of the first equalization circuit structure 150, the second equalization circuit structure 162, the third equalization circuit structure 164, and the fourth equalization circuit structure 166 may receive a feedback sampling signal as feedback and perform an equalization operation intended to solve issues caused by intersymbol interference based on the feedback. Here, the first equalization circuit structure 150 may receive data one UI earlier as feedback, the second equalization circuit structure 162 may receive data two UIs earlier, the third equalization circuit structure 164 may receive data three UIs earlier, and the fourth equalization circuit structure 166 may receive data four UIs earlier.

In some implementations, the sampler 130 may receive a third control signal CTRL_3 from the control logic circuit 200. In order to perform an offset calibration operation, the control logic circuit 200 may transmit the third control signal CTRL_3 to the sampler 130. The sampler 130, in response to receiving the third control signal CTRL_3, may maintain the equalization coefficient reflected in the sampling signals SA_OUT, SA_OUTB at a constant value. Alternatively, the sampler 130 may update a calibration code associated with the first equalization circuit structure 150 based on the third control signal CTRL_3 or operate to store the calibration code in transistors included in the first equalization circuit structure 150. Through this, a calibration operation for the voltage offset arising in each feedback path of the sampler 130 having various feedback paths may be performed. Consequently, a voltage offset due to mismatch among a plurality of transistors included in the sampling circuit 140 or the first equalization circuit structure 150 may be improved.

The control logic circuit 200 may be configured to generally control the receive circuit 100 so as to perform an offset calibration operation for the receive circuit 100.

The control logic circuit 200 may perform an offset calibration operation for a plurality of feedback paths of the receive circuit 100 by transmitting control signals (for example, the first control signal CTRL_1, the second control signal CTRL_2, and the third control signal CTRL_3) to the receive circuit 100. For example, the control logic circuit 200 may keep the amplified signals BUF_OUT, BUF_OUTB output from the buffer 110 at a supply voltage by transmitting the first control signal CTRL_1 to the buffer 110. Also, the control logic circuit 200 may set the summer output signals SUM_OUT, SUM_OUTB from the summer 120 to certain values by transmitting the second control signal CTRL_2 to the second equalization circuit structure 162 and determine a feedback path in which the offset calibration operation is performed.

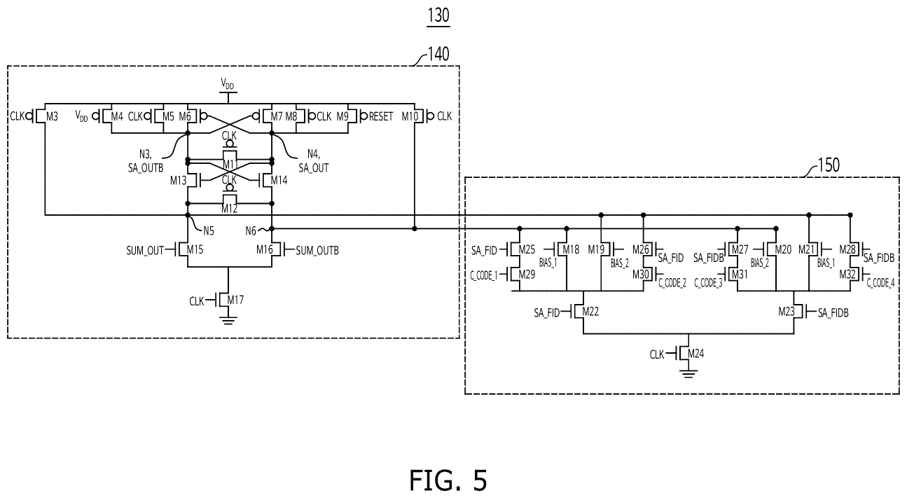

In addition, the control logic circuit 200 may receive the sampling signals SA_OUT, SA_OUTB from the sampler 130 and, in response, update a calibration code or store the calibration code in transistors included in the first equalization circuit structure 150 through the third control signal CTRL_3. In some implementations, the control logic circuit 200 may determine an offset compensation signal and input (e.g., transmit) the determined offset compensation signal into gates of transistors included in the first equalization circuit structure 150 (for example, M29, M30, M31, M32 in FIG. 5).

In the present disclosure, terms such as “calibration code,” “offset calibration code,” “offset compensation code,” and “offset compensation signal” have the same meaning and may be used interchangeably depending on context.

Although not illustrated, the summer 120 may include a first summer and a second summer. The first summer may generate a first summer output signal based on the amplified signals BUF_OUT, BUF_OUTB. The second summer may generate a second summer output signal based on the amplified signals BUF_OUT, BUF_OUTB. The first summer output signal may be provided to a first sampling circuit and a third sampling circuit, and the second summer output signal may be provided to a second sampling circuit and a fourth sampling circuit, which will be described below.

The sampling circuit 140 may include a first sampling circuit, a second sampling circuit, a third sampling circuit, and a fourth sampling circuit. Each of the first to fourth sampling circuits may receive a clock signal having a 90-degree phase difference and generate a sampling signal in synchronization with that clock signal. For example, the first sampling circuit may generate a first sampling signal in accordance with a first clock signal, the second sampling circuit may generate a second sampling signal in accordance with a second clock signal, the third sampling circuit may generate a third sampling signal in accordance with a third clock signal, and the fourth sampling circuit may generate a fourth sampling signal in accordance with a fourth clock signal.

The first clock signal, the second clock signal, the third clock signal, and the fourth clock signal may be clock signals each having a 90-degree phase difference, having the same frequency while generating signals at different time points. For example, if the first clock signal is a reference clock signal, the second clock signal may have a phase delayed by 90 degrees compared to the first clock signal. In addition, the third clock signal may have a 180-degree phase difference from the first clock signal and a phase delayed by 90 degrees from the second clock signal. Similarly, the fourth clock signal may have a 180-degree phase difference from the second clock signal and a phase delayed by 90 degrees from the third clock signal. In some implementations, the first to fourth clock signals may be generated by the control logic circuit 200.

Also, the first equalization circuit structure 150 may include a 1_1 equalization circuit (also referred to as a first equalization circuit in the present disclosure), a 1_2 equalization circuit (also referred to as a second equalization circuit in the present disclosure), a 1_3 equalization circuit (also referred to as a third equalization circuit in the present disclosure), and a 1_4 equalization circuit (also referred to as a fourth equalization circuit in the present disclosure). The 1_1 equalization circuit may be connected to the first sampling circuit and configured to equalize the first sampling signal, the 1_2 equalization circuit may be connected to the second sampling circuit and configured to equalize the second sampling signal, the 1_3 equalization circuit may be connected to the third sampling circuit and configured to equalize the third sampling signal, and the 1_4 equalization circuit may be connected to the fourth sampling circuit and configured to equalize the fourth sampling signal.

For example, the first sampling signal generated by the first sampling circuit may be directly input to the 1_2 equalization circuit, and the 1_2 equalization circuit may equalize the second sampling signal based on the first sampling signal sampled prior to the sampling time of the second sampling signal. Similarly, the second sampling signal generated by the second sampling circuit may be directly input to the 1_3 equalization circuit, and the 1_3 equalization circuit may equalize the third sampling signal based on the second sampling signal sampled prior to the sampling time of the third sampling signal.

In this manner, various feedback paths may be configured by the circuits included in the sampler 130. For example, there may be a feedback path formed by the first sampling signal generated by the first sampling circuit being input as feedback data to the 1_2 equalization circuit, and, based on that, the second sampling circuit generating the second sampling signal. Additionally, there may be a feedback path formed by the second sampling signal generated by the second sampling circuit being input as feedback data to the 1_3 equalization circuit, and, based on that, the third sampling circuit generating the third sampling signal. The feedback paths included in the sampler 130 are not limited to the above examples.

Depending on the implementation, a feedback path may be referred to as a sampling path.

According to various implementations of the present disclosure, a calibration operation may be performed for a voltage offset along a plurality of feedback paths of the receive circuit 100. Through this, a voltage offset arising from mismatch among a plurality of elements included in the receive circuit 100 may be effectively calibrated, and data signal accuracy and reliability may be improved.

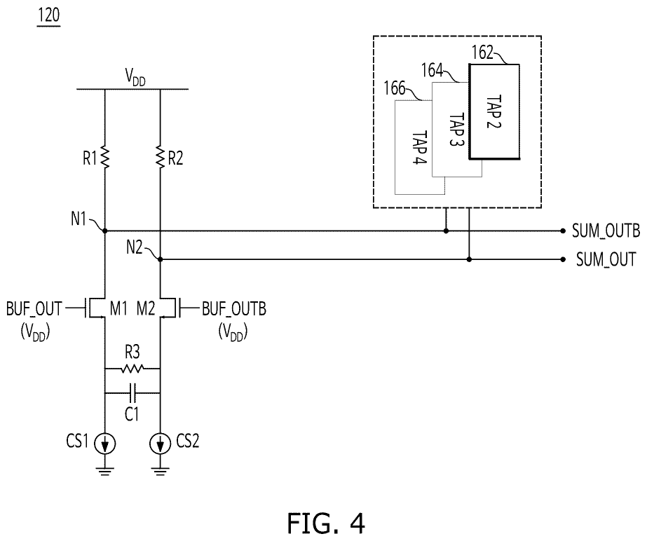

FIG. 4 is a diagram for explaining a summer according to some implementations of the present disclosure.

Referring to FIG. 4, the summer 120 may include first through third resistors R1, R2, R3, first through second transistors M1, M2, a first capacitor C1, and first through second current sources CS1, CS2.

The summer 120 may receive the amplified signals BUF_OUT, BUF_OUTB and output the summer output signals SUM_OUT, SUM_OUTB. The amplified signals BUF_OUT, BUF_OUTB may be signals output from the buffer 110 of FIG. 3. The summer output signals SUM_OUT, SUM_OUTB may be signals in which waveforms of the amplified signals BUF_OUT, BUF_OUTB are adjusted or the amplitude thereof is increased. Depending on the implementation, the amplified signals BUF_OUT, BUF_OUTB and the summer output signals SUM_OUT, SUM_OUTB may each be composed of differential signals.

The first transistor M1 may receive the amplified signal BUF_OUT through its gate terminal. The drain terminal of the first transistor M1 may be connected to a first node N1 along with one end of the first resistor R1. The other end of the first resistor R1 may be connected to the supply voltage VDD. The source terminal of the first transistor M1 may be connected to the first current source CS1, one end of the third resistor R3, and one end of the first capacitor C1. The first transistor M1 may control the amount of current flowing between its drain terminal and its source terminal or may operate as a switch, depending on the amplified signal BUF_OUT. In some implementations, the first transistor M1 may be implemented as an NMOS transistor, but it is not limited thereto.

The second transistor M2 may receive the amplified signal BUF_OUTB through its gate terminal. The drain terminal of the second transistor M2 may be connected to a second node N2 along with one end of the second resistor R2. The other end of the second resistor R2 may be connected to the supply voltage VDD. The source terminal of the second transistor M2 may be connected to the second current source CS2, the other end of the third resistor R3, and the other end of the first capacitor C1. The second transistor M2 may control the amount of current flowing between its drain terminal and its source terminal or may operate as a switch, depending on the amplified signal BUF_OUTB. In some implementations, the second transistor M2 may be implemented as an NMOS transistor, but it is not limited thereto.

The first current source CS1 may generate a bias current flowing through the first transistor M1. The second current source CS2 may generate a bias current flowing through the second transistor M2. In some implementations, each of the current sources CS1, CS2 may be a transistor that receives a bias voltage through a gate terminal, is connected to the transistors M1, M2 respectively through a drain terminal, and is connected to ground voltage through a source terminal.

The third resistor R3 and the first capacitor C1 may be connected in parallel between the source terminals of the transistors M1, M2. The third resistor R3 and the first capacitor C1 may amplify, compensate, or restore high-frequency components of a transmitted signal that may be weakened due to channel loss. Based on these properties, the summer 120 may be implemented as a continuous-time linear equalizer (CTLE).

According to the illustrated implementation, the summer 120 may receive the amplified signals BUF_OUT, BUF_OUTB to generate the summer output signals SUM_OUT, SUM_OUTB. In some implementations, the summer 120 may compare and amplify the voltage difference of the input differential signals so as to generate an output signal. From this viewpoint, the summer 120 may be implemented as a variable gain amplifier (VGA).

In some implementations, at least one of the second equalization circuit structure 162, the third equalization circuit structure 164, and the fourth equalization circuit structure 166 may be connected to each of the lines on which the summer output signals SUM_OUT, SUM_OUTB are formed. At least one of the second equalization circuit structure 162, the third equalization circuit structure 164, or the fourth equalization circuit structure 166 may be configured to equalize the summer output signals SUM_OUT, SUM_OUTB based on signals fed back from the sampler 130 of FIG. 3.

During the offset calibration operation according to the present disclosure, the amplified signals BUF_OUT, BUF_OUTB input to the first transistor M1 and the second transistor M2 may be maintained at the supply voltage VDD. This is for ensuring reliability of subsequent operations by maintaining a fixed reference signal during the calibration process.

In addition, the summer output signals SUM_OUT, SUM_OUTB output from the summer 120 may be set to certain values by the second equalization circuit structure 162. For example, to set the summer output signal SUM_OUT to a low level and the summer output signal SUM_OUTB to a high level, the second equalization circuit structure 162 may lower the voltage level of the line connected to the second node N2 while maintaining the voltage level of the line connected to the first node N1. Through this, the input signal state provided to the sampler 130 of FIG. 3 may be suitably determined for the calibration operation, and the feedback path in which the offset calibration operation is performed may be clearly defined.

In some implementations, while the offset calibration operation is performed, the third equalization circuit structure 164 and the fourth equalization circuit structure 166 may be deactivated or controlled by the control logic circuit 200 so that the third equalization circuit structure 164 and the fourth equalization circuit structure 166 do or do not affect the summer output signals SUM_OUT, SUM_OUTB.

In some implementations, in the receive circuit illustrated in FIG. 3, assuming that the currently sampled signal is referred to as a “current sampling signal” and the sampling signal input to the first equalization circuit structure 150 is referred to as a “previous sampling signal,” a sampling signal input to the second equalization circuit structure 162 may be an even earlier sampling signal than the previous sampling signal. For example, the previous sampling signal may be a signal sampled before the current sampling signal, and the sampling signal input to the second equalization circuit structure 162 may be a signal sampled further earlier than the previous sampling signal.

FIG. 5 is a diagram for explaining a sampler according to some implementations of the present disclosure.

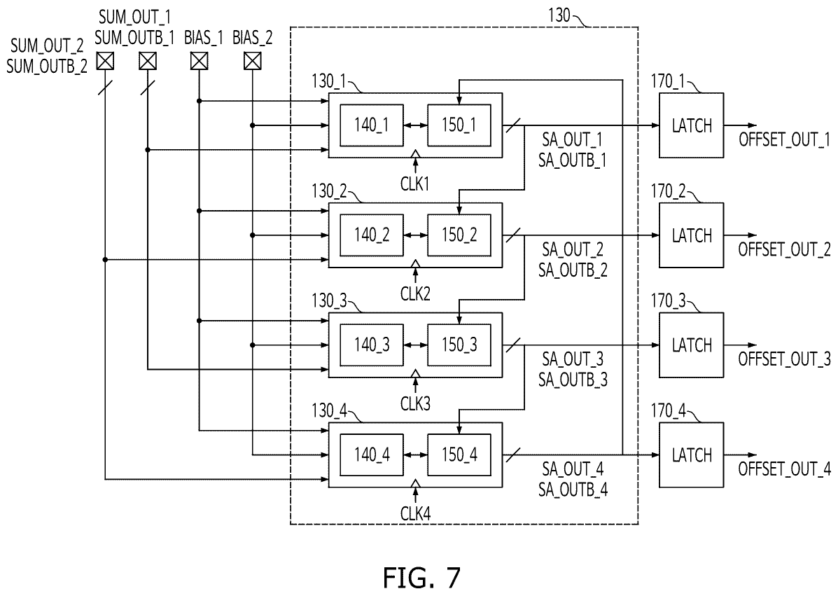

Referring to FIG. 5, the sampler 130 may include a sampling circuit 140 and a first equalization circuit structure 150. The sampling circuit 140 shown in FIG. 5 may be any one of the first to fourth sampling circuits (see FIG. 7), and the first equalization circuit structure 150 shown in FIG. 5 may be any one of the corresponding 1_1 through 1_4 equalization circuits (see FIG. 7).

The sampling circuit 140 may receive the summer output signals SUM_OUT, SUM_OUTB, sample the summer output signals SUM_OUT, SUM_OUTB based on a clock signal CLK, and generate sampling signals SA_OUT, SA_OUTB. The generated sampling signals SA_OUT, SA_OUTB may be output through a third node N3 and a fourth node N4. The first equalization circuit structure 150 may be connected to the sampling circuit 140 through lines connected to a fifth node N5 and a sixth node N6.

In other words, the third node N3 and the fourth node N4 may be nodes that output the sampling signals SA_OUT, SA_OUTB. Also, the fifth node N5 and the sixth node N6 may be nodes connecting the sampling circuit 140 and the first equalization circuit structure 150.

The first equalization circuit structure 150 may receive feedback sampling signals SA_FID, SA_FIDB and may equalize the sampling signals SA_OUT, SA_OUTB based on the feedback sampling signals SA_FID, SA_FIDB. Here, the feedback sampling signals SA_FID, SA_FIDB may be signals sampled 1 UI earlier than the sampling signals SA_OUT, SA_OUTB.

In addition, the first equalization circuit structure 150 may receive calibration codes C_CODE_1, C_CODE_2, C_CODE_3, C_CODE_4 and operate so as to remove the voltage offset of the sampler 130 based on the calibration codes C_CODE_1, C_CODE_2, C_CODE_3, C_CODE_4. For example, the first equalization circuit structure 150 may be configured to adjust the voltage level of nodes (for example, N5, N6) connected to the sampling circuit 140 based on the calibration codes C_CODE_1, C_CODE_2, C_CODE_3, C_CODE_4. Through this, a voltage offset of the sampler 130 may be removed.

The sampling circuit 140 may include third through seventeenth transistors M3 through M17. The third through twelfth transistors M3 through M12 may be implemented as PMOS transistors, and the thirteenth through seventeenth transistors M13 through M17 may be implemented as NMOS transistors, but they are not limited thereto.

The third transistor M3 may receive the clock signal CLK through a gate, receive the supply voltage VDD through a source, and be connected to the fifth node N5 through a drain. The fifth transistor M5 may receive the clock signal CLK through a gate, receive the supply voltage VDD through a source, and be connected to the third node N3 through a drain. The eighth transistor M8 may receive the clock signal CLK through a gate, receive the supply voltage VDD through a source, and be connected to the fourth node N4 through a drain. The tenth transistor M10 may receive the clock signal CLK through a gate, receive the supply voltage VDD through a source, and be connected to the sixth node N6 through a drain. Each of the third transistor M3, the fifth transistor M5, the eighth transistor M8, and the tenth transistor M10 may control the amount of current flowing between the source terminal and the drain terminal or may operate as a switch, depending on the state (e.g., high or low) of the clock signal CLK. Additionally, each of the third transistor M3, the fifth transistor M5, the eighth transistor M8, and the tenth transistor M10 may perform a precharge operation on the connected nodes.

The fourth transistor M4 may receive the supply voltage VDD through a gate, receive the supply voltage VDD through a source, and be connected to the third node N3 through a drain.

The sixth transistor M6 may be connected to the fourth node N4 through a gate, receive the supply voltage VDD through a source, and be connected to the third node N3 through a drain. The seventh transistor M7 may be connected to the third node N3 through a gate, receive the supply voltage VDD through a source, and be connected to the fourth node N4 through a drain. In other words, the sixth transistor M6 and the seventh transistor M7 may be transistors into which the sampling signals SA_OUT, SA_OUTB are input through gates.

The eleventh transistor M11 may receive the clock signal CLK through a gate, be connected to the third node N3 through a source, and be connected to the fourth node N4 through a drain. The twelfth transistor M12 may receive the clock signal CLK through a gate, be connected to the fifth node N5 through a source, and be connected to the sixth node N6 through a drain. Each of the eleventh transistor M11 and the twelfth transistor M12 may operate to keep the voltage levels of connected nodes in equilibrium. Specifically, the eleventh transistor M11 may adjust voltages of the third node N3 and the fourth node N4 depending on the state of the clock signal CLK, and the twelfth transistor M12 may maintain equal voltages of the fifth node N5 and the sixth node N6.

The ninth transistor M9 may receive a reset signal RESET through a gate, receive the supply voltage VDD through a source, and be connected to the fourth node N4 through a drain. The ninth transistor M9 may set initial states of the sampling circuit 140 and the first equalization circuit structure 150 based on the reset signal RESET. The ninth transistor M9 may be referred to as a reset transistor. The reset signal RESET may become active for a time interval from about 2 UI before the start of the sampling operation until about 2 UI after the start of the sampling operation, and during this interval, the sampling signals SA_OUT, SA_OUTB may be set to an initial value (for example, logical “1”). Through this, the sampling signals may maintain a stable initial state, and the accuracy of subsequent sampling operations may be improved.

In the implementation of the present disclosure, a reset effect may be implemented through a single PMOS transistor (for example, the ninth transistor M9) in a simplified structure without implementing a logic circuit. Also, the ninth transistor M9 may be designed to have a necessary size (W/L ratio) so that node voltages may be quickly controlled in order to offset the effect of the first equalization circuit structure 150 based on the reset signal RESET. Through this, the ninth transistor M9 may maintain the sampling signal SA_OUT at a first logic level (for example, a high level) based on the reset signal RESET. In some implementations, the ratio of the width to the length (W/L) of the channel of the ninth transistor M9 may be greater than the ratio of the width to the length (W/L) of each of the eighteenth through twenty-first transistors M18 through M21. Through this, the sampler 130 may perform a stable reset operation without complex logic, and simplicity and efficiency of the sampling circuit 140 may be maintained.

The thirteenth transistor M13 may be connected to the fourth node N4 through a gate, connected to the third node N3 through a drain, and connected to the fifth node N5 through a source. The fourteenth transistor M14 may be connected to the third node N3 through a gate, connected to the fourth node N4 through a drain, and connected to the sixth node N6 through a source.

The fifteenth transistor M15 may receive the summer output signal SUM_OUT through a gate, be connected to the fifth node N5 through a drain, and be connected to a drain of the seventeenth transistor M17 through a source. The sixteenth transistor M16 may receive the summer output signal SUM_OUTB through a gate, be connected to the sixth node N6 through a drain, and be connected to a drain of the seventeenth transistor M17 through a source. The seventeenth transistor M17 may receive the clock signal CLK through a gate, be connected to the sources of the fifteenth transistor M15 or the sixteenth transistor M16 through a drain, and be connected to a ground terminal through a source. In other words, the fifteenth transistor M15 and the sixteenth transistor M16 may be transistors into which the summer output signals SUM_OUT, SUM_OUTB are input through gates.

The first equalization circuit structure 150 may include eighteenth through thirty-second transistors M18 through M32. The eighteenth through thirty-second transistors M18 through M32 may be implemented as NMOS transistors but are not limited thereto.

The eighteenth transistor M18 (also referred to as a second transistor of a second transistor structure in the present disclosure) may receive a first bias voltage BIAS_1 through a gate, be connected to the sixth node N6 through a drain, and be connected to a drain of the twenty-second transistor M22 through a source. It is to be noted that here the second transistor of the second transistor structure of the first equalization circuit structure 150 may not be the second transistor M2 of the summer 120. The nineteenth transistor M19 (also referred to as a third transistor of the second transistor structure in the present disclosure) may receive a second bias voltage BIAS_2 through a gate, be connected to the fifth node N5 through a drain, and be connected to a drain of the twenty-second transistor M22 through a source. It is to be noted that the third transistor of the second transistor structure of the first equalization circuit structure 150 may not be the third transistor M3 of the summer 120. The twentieth transistor M20 may receive the second bias voltage BIAS_2 through a gate, be connected to the sixth node N6 through a drain, and be connected to a drain of the twenty-third transistor M23 through a source. The twenty-first transistor M21 may receive the first bias voltage BIAS_1 through a gate, be connected to the fifth node N5 through a drain, and be connected to a drain of the twenty-third transistor M23 through a source. According to the voltage difference between the first bias voltage BIAS_1 and the second bias voltage BIAS_2, the amount of current flowing from the fifth node N5 or the sixth node N6 to the ground terminal may be adjusted. Through this, the first equalization circuit structure 150 may perform an equalization operation to reduce intersymbol interference of the input signal and improve signal quality.

In some implementations, while the offset calibration operation according to the present disclosure is performed, the voltage levels of the bias voltages BIAS_1, BIAS_2 input to each of the eighteenth transistor M18, the nineteenth transistor M19, the twentieth transistor M20, and the twenty-first transistor M21 may be maintained equally. For example, when the control logic circuit 200 performs the offset calibration operation, the control logic circuit 200 may keep the first bias voltage BIAS_1 and the second bias voltage BIAS_2 at the same level. This may correspond to a time interval in which the control logic circuit 200 transmits the first control signal CTRL_1 or the second control signal CTRL_2, but is not limited thereto. Through this, a fixed reference signal may be maintained during the calibration process, and accuracy and stability of the offset calibration operation through the feedback path may be ensured.

The twenty-second transistor M22 may receive the feedback sampling signal SA_FID through a gate, be connected to the eighteenth transistor M18 or the nineteenth transistor M19 through a drain, and be connected to a drain of the twenty-fourth transistor M24 through a source. The twenty-third transistor M23 may receive the feedback sampling signal SA_FIDB through a gate, be connected to the twentieth transistor M20 or the twenty-first transistor M21 through a drain, and be connected to a drain of the twenty-fourth transistor M24 through a source. Each of the twenty-second transistor M22 and the twenty-third transistor M23 may be configured to operate as a switch controlling current flow, depending on the state of the feedback sampling signals SA_FID, SA_FIDB. For example, if the feedback sampling signal SA_FID is at a high level and the feedback sampling signal SA_FIDB is at a low level, the twenty-second transistor M22 may be on, and the twenty-third transistor M23 may be off. In other words, if the feedback sampling signal is input through the gate of the twenty-second transistor M22, a differential signal of that feedback sampling signal may be input through the gate of the twenty-third transistor M23. Thus, a feedback path through which current flows may be defined by the feedback sampling signal SA_FID, and a calibration operation may be performed for that path.

Similarly, the twenty-fifth transistor M25 (also referred to as a sixth transistor of a fourth transistor structure in the present disclosure) may receive the feedback sampling signal SA_FID through a gate, be connected to the sixth node N6 through a drain, and be connected to a drain of the twenty-ninth transistor M29 through a source. It is to be noted that the sixth transistor of the fourth transistor structure of the first equalization circuit structure 150 may not be the sixth transistor M6 of sampling circuit 140. The twenty-sixth transistor M26 (also referred to as a seventh transistor of the fourth transistor structure in the present disclosure) may receive the feedback sampling signal SA_FID through a gate, be connected to the fifth node N5 through a drain, and be connected to a drain of the thirtieth transistor M30 through a source. It is to be noted that the seventh transistor of the fourth transistor structure of the first equalization circuit structure 150 may not be the seventh transistor M7 of sampling circuit 140. The twenty-seventh transistor M27 may receive the feedback sampling signal SA_FIDB through a gate, be connected to the sixth node N6 through a drain, and be connected to a drain of the thirty-first transistor M31 through a source. The twenty-eighth transistor M28 may receive the feedback sampling signal SA_FIDB through a gate, be connected to the fifth node N5 through a drain, and be connected to a drain of the thirty-second transistor M32 through a source.

Each of the twenty-fifth transistor M25, the twenty-sixth transistor M26, the twenty-seventh transistor M27, and the twenty-eighth transistor M28 may be configured to operate as a switch controlling current flow, depending on the states of the feedback sampling signals SA_FID, SA_FIDB. For example, if the feedback sampling signal SA_FID is at a high level and the feedback sampling signal SA_FIDB is at a low level, the twenty-fifth transistor M25 and the twenty-sixth transistor M26 may be on, and the twenty-seventh transistor M27 and the twenty-eighth transistor M28 may be off. As a result, in the feedback path through which current flows via the twenty-second transistor M22, a voltage offset due to mismatch between paired elements (for example, the eighteenth transistor M18 and the nineteenth transistor M19) may be improved. Also, in the process, the effect of a voltage offset due to mismatch between elements (for example, the twentieth transistor M20 and the twenty-first transistor M21) that are not included in the selected feedback path may be minimized.

The twenty-fourth transistor M24 may receive the clock signal CLK through its gate, be connected to the source of the twenty-second transistor M22 or the source of the twenty-third transistor M23 through its drain, and be connected to a ground terminal through its source.

The twenty-ninth transistor M29 (also referred to as a fourth transistor of a third transistor structure in the present disclosure) may receive a first calibration code C_CODE_1 through a gate, be connected to the source of the twenty-fifth transistor M25 through a drain, and be connected to the drain of the twenty-second transistor M22 through a source. It is to be noted that the fourth transistor of the third transistor structure of the first equalization circuit structure 150 may not be the fourth transistor M4 of sampling circuit 140. The thirtieth transistor M30 (also referred to as a fifth transistor of the third transistor structure in the present disclosure) may receive a second calibration code C_CODE_2 through a gate, be connected to the source of the twenty-sixth transistor M26 through a drain, and be connected to the drain of the twenty-second transistor M22 through a source. It is to be noted that the fifth transistor of the third transistor structure of the first equalization circuit structure 150 may not be the fifth transistor M5 of sampling circuit 140. The thirty-first transistor M31 may receive a third calibration code C_CODE_3 through a gate, be connected to the source of the twenty-seventh transistor M27 through a drain, and be connected to the drain of the twenty-third transistor M23 through a source. The thirty-second transistor M32 may receive a fourth calibration code C_CODE_4 through a gate, be connected to the source of the twenty-eighth transistor M28 through a drain, and be connected to the drain of the twenty-third transistor M23 through a source.

In some implementations, the twenty-ninth transistor M29 may be connected between the twenty-second transistor M22 and the sixth node N6, and the thirtieth transistor M30 may be connected between the twenty-second transistor M22 and the fifth node N5. Also, the thirty-first transistor M31 may be connected between the twenty-third transistor M23 and the sixth node N6, and the thirty-second transistor M32 may be connected between the twenty-third transistor M23 and the fifth node N5.

The twenty-ninth transistor M29 and the thirtieth transistor M30, and the thirty-first transistor M31 and the thirty-second transistor M32 may form pairs configured to compensate for a voltage offset due to differences in electrical characteristics of elements that may occur in each feedback path. For example, in the feedback path formed when the feedback sampling signal SA_FID is high, the twenty-ninth transistor M29 and the thirtieth transistor M30 may compensate for a voltage offset due to electrical characteristic differences between the eighteenth transistor M18 and the nineteenth transistor M19, based on the calibration codes C_CODE_1, C_CODE_2. During this process, the voltage levels of the fifth node N5 and the sixth node N6 may be adjusted during sampling, and the offset may be effectively removed. Likewise, in the feedback path formed when the feedback sampling signal SA_FID is low, a voltage offset due to electrical characteristic differences between the twentieth transistor M20 and the twenty-first transistor M21 may be compensated for based on the calibration codes C_CODE_3, C_CODE_4.

In some implementations, the first calibration code C_CODE_1 and the second calibration code C_CODE_2 may be associated with a voltage offset difference between the eighteenth transistor M18 and the nineteenth transistor M19, and the third calibration code C_CODE_3 and the fourth calibration code C_CODE_4 may be associated with a voltage offset difference between the twentieth transistor M20 and the twenty-first transistor M21. Additionally, the first calibration code C_CODE_1 and the second calibration code C_CODE_2, as well as the third calibration code C_CODE_3 and the fourth calibration code C_CODE_4, may each be associated with a voltage offset difference between the fifteenth transistor M15 and the sixteenth transistor M16.

For example, in the feedback path formed when the feedback sampling signal SA_FID is at a high level, the degree to which the twenty-ninth transistor M29 reduces the voltage level of the sixth node N6 and the degree to which the thirtieth transistor M30 reduces the voltage level of the fifth node N5 may each be controlled based on the first calibration code C_CODE_1 and the second calibration code C_CODE_2. Also, the first calibration code C_CODE_1 and the second calibration code C_CODE_2 may be obtained through a series of steps in which the feedback sampling signal (or offset signal) is acquired via the feedback path that is formed when the feedback sampling signal SA_FID is at a high level for a certain period, and the voltage offset level is measured based on the acquired value. A more detailed description of how to obtain the calibration codes will be provided below.

In some implementations, each of the twenty-ninth transistor M29, the thirtieth transistor M30, the thirty-first transistor M31, and the thirty-second transistor M32 may each include a plurality of sub-transistors, depending on the number of bits in the calibration code C_CODE. That is, each of the twenty-ninth transistor M29, the thirtieth transistor M30, the thirty-first transistor M31, and the thirty-second transistor M32 may include a plurality of sub-transistors in parallel, corresponding to the number of bits in the calibration code C_CODE. For example, if the calibration code C_CODE has 3 bits, each transistor may be implemented with three sub-transistors connected in parallel. However, the scope of the present disclosure is not limited thereto. The number of bits of the calibration code C_CODE may be variously set, and each of the twenty-ninth transistor M29, the thirtieth transistor M30, the thirty-first transistor M31, and the thirty-second transistor M32 may be appropriately configured in number according to the calibration code C_CODE.

According to various implementations of the present disclosure, transistors (for example, M18, M19, M20, M21) that determine the equalization coefficient may be disposed between a transistor (for example, M22, M23) into which a feedback sampling signal SA_FID, SA_FIDB sampled 1 UI earlier than the sampling signals SA_OUT and the sampling circuit 140. Also, by disposing the transistors that determine the equalization coefficient above the transistor into which the feedback sampling signals SA_FID, SA_FIDB are input, the current flow path of the feedback signals may be set more succinctly. Through this configuration, signal delay that arises in the feedback path may be reduced, and feedback time may be effectively decreased.

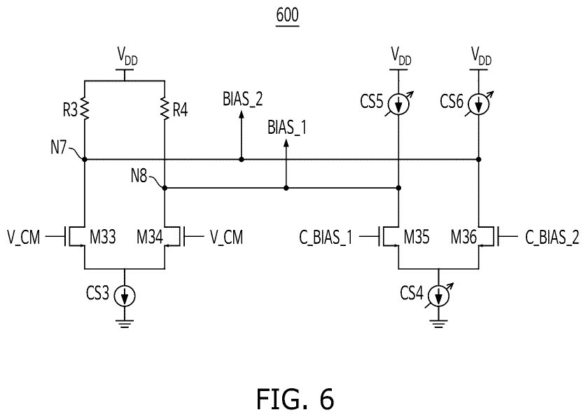

FIG. 6 is a diagram for explaining a bias voltage generation circuit according to some implementations of the present disclosure.

Referring to FIG. 6, the bias voltage generation circuit 600 may include third and fourth resistors R3, R4, transistors M33 through M36, and current sources CS3 through CS6. The transistors M33 through M36 may be implemented as NMOS transistors, but they are not limited thereto.

The bias voltage generation circuit 600 may be configured to output a first bias voltage BIAS_1 and a second bias voltage BIAS_2 based on a first bias control signal C_BIAS_1 and a second bias control signal C_BIAS_2. Also, the bias voltage generation circuit 600 may be configured to generate the first bias voltage BIAS_1 and the second bias voltage BIAS_2 based on a bias current generated by the current sources CS3 through CS6. The first bias voltage BIAS_1 and the second bias voltage BIAS_2 output by the bias voltage generation circuit 600 may be provided to the first equalization circuit structure 150 of FIG. 5.

One end of the third resistor R3 may be connected to the supply voltage VDD, and the other end of the third resistor R3 may be connected to a seventh node N7. One end of the fourth resistor R4 may be connected to the supply voltage VDD, and the other end of the fourth resistor R4 may be connected to an eighth node N8.

The thirty-third transistor M33 may receive a common voltage V_CM through a gate, be connected to the seventh node N7 through a drain, and be connected to the third current source CS3 through a source. The thirty-fourth transistor M34 may receive the common voltage V_CM through a gate, be connected to the eighth node N8 through a drain, and be connected to the third current source CS3 through a source.

The third current source CS3 may generate a bias current flowing through the thirty-third transistor M33 and the thirty-fourth transistor M34. In some implementations, the third current source CS3 may be a transistor that receives a bias voltage through a gate terminal, is connected to the transistors M33, M34 through a drain terminal, and is connected to ground voltage through a source terminal.

The thirty-fifth transistor M35 may receive the first bias control signal C_BIAS_1 through a gate, be connected to the eighth node N8 through a drain, and be connected to a fourth current source CS4 through a source. The thirty-sixth transistor M36 may receive the second bias control signal C_BIAS_2 through a gate, be connected to the seventh node N7 through a drain, and be connected to the fourth current source CS4 through a source. In some implementations, each of the thirty-fifth transistor M35 and the thirty-sixth transistor M36 may be configured to operate as a switch controlling current flow depending on the state of the bias control signals C_BIAS_1, C_BIAS_2. For example, if the first bias control signal C_BIAS_1 is at a high level and the second bias control signal C_BIAS_2 is at a low level, the thirty-fifth transistor M35 may be on, and the thirty-sixth transistor M36 may be off. As a result, a path of current flow may be established through the thirty-fifth transistor M35.

In some implementations, the control logic circuit (for example, 200 in FIG. 3) may provide the first bias control signal C_BIAS_1 and the second bias control signal C_BIAS_2 to the bias voltage generation circuit 600.

In some implementations, the first bias control signal C_BIAS_1 and the second bias control signal C_BIAS_2 may be determined based on tap polarity of the first equalization circuit structure 150. For example, if the first equalization circuit structure 150 has a first tap polarity, the first bias control signal C_BIAS_1 may be a high level so that the thirty-fifth transistor M35 is activated (or strongly inverted), and the second bias control signal C_BIAS_2 may be a low level so that the thirty-sixth transistor M36 is deactivated (or weakly inverted, intermediate inversion). In this case, the first bias voltage BIAS_1 may be lower than the second bias voltage BIAS_2. Conversely, if the first equalization circuit structure 150 has a second tap polarity, the first bias control signal C_BIAS_1 may be a low level so that the thirty-fifth transistor M35 is deactivated (or weakly inverted, intermediate inversion), and the second bias control signal C_BIAS_2 may be a high level so that the thirty-sixth transistor M36 is activated (or strongly inverted). In this case, the first bias voltage BIAS_1 may be higher than the second bias voltage BIAS_2. Through such a configuration, the first bias voltage BIAS_1 and the second bias voltage BIAS_2 output from the bias voltage generation circuit 600 may be controlled. The tap polarity associated with the first equalization circuit structure 150 may be determined by the control logic circuit 200.

The fourth current source CS4 may generate a bias current flowing through the thirty-fifth transistor M35 or the thirty-sixth transistor M36. In some implementations, the fourth current source CS4 may be a transistor that receives a bias voltage through a gate terminal, is connected to the transistors M35, M36 through a drain terminal, and is connected to ground voltage through a source terminal. Depending on the magnitude of the bias current generated by the fourth current source CS4, the difference between the first bias voltage BIAS_1 and the second bias voltage BIAS_2 output by the bias voltage generation circuit 600 may be adjusted. Through this, the equalization coefficient applied to the first equalization circuit structure 150 of FIG. 5 may be controlled. The magnitude of the bias current generated by the fourth current source CS4 may be controlled by a component separate from the receive circuit 100 of FIG. 1 (the control logic circuit 200 of FIG. 3).

The difference between the first bias voltage BIAS_1 and the second bias voltage BIAS_2 may determine the ratio of current branched to the first equalization circuit structure 150 through the fifth node N5 and the sixth node N6, which may be called as the “equalization coefficient.” The equalization coefficient is a measure representing how strongly to perform voltage level adjustments through the first equalization circuit structure 150 and may serve as an important parameter for optimizing signal compensation of the feedback path.

The fifth current source CS5 may generate a bias current flowing through a line connected to the eighth node N8. The sixth current source CS6 may generate a bias current flowing through a line connected to the seventh node N7. In some implementations, the magnitudes of the bias currents generated by the fifth current source CS5 and the sixth current source CS6 may be the same, but they are not limited thereto.

In some implementations, while the offset calibration operation according to the present disclosure is performed, the thirty-fifth transistor M35 and the thirty-sixth transistor M36 may receive bias control signals C_BIAS_1, C_BIAS_2 of the same level from the control logic circuit. Consequently, the voltage levels of the first bias voltage BIAS_1 and the second bias voltage BIAS_2 output from the bias voltage generation circuit 600 may be kept equal. This configuration is intended to maintain a fixed reference signal during the calibration process so as to secure accuracy and stability of the offset calibration operation through the feedback path.

According to various implementations of the present disclosure, the difference between the first bias voltage BIAS_1 and the second bias voltage BIAS_2 output by the bias voltage generation circuit 600 may be adjusted based on the bias current generated by the fourth current source CS4. That is, the equalization coefficient may be determined based on the bias current generated by the fourth current source CS4. Through this configuration, the equalization coefficient applied to the first equalization circuit structure 150 may remain stable regardless of variations in the supply voltage VDD.

FIG. 7 is a diagram for explaining a sampler according to some implementations of the present disclosure.

Referring to FIG. 7, the sampler 130 may include a first sampler 130_1, which includes a first sampling circuit 140_1 and a 1_1 equalization circuit 150_1; a second sampler 130_2, which includes a second sampling circuit 140_2 and a 1_2 equalization circuit 150_2; a third sampler 130_3, which includes a third sampling circuit 140_3 and a 1_3 equalization circuit 150_3; and a fourth sampler 130_4, which includes a fourth sampling circuit 140_4 and a 1_4 equalization circuit 150_4.

The first sampler 130_1 may sample a first summer output signal SUM_OUT_1, SUM_OUTB_1 according to a first clock signal CLK1 to generate first sampling signals SA_OUT_1, SA_OUTB_1. Specifically, the first sampling circuit 140_1 may sample the first summer output signal SUM_OUT_1, SUM_OUTB_1 in synchronization with the first clock signal CLK1. In addition, the 1_1 equalization circuit 150_1 may equalize the first sampling signals SA_OUT_1, SA_OUTB_1 in synchronization with the first clock signal CLK1. The 1_1 equalization circuit 150_1 may apply an equalization coefficient acquired based on a difference between the first bias voltage BIAS_1 and the second bias voltage BIAS_2 so as to equalize the first sampling signals SA_OUT_1, SA_OUTB_1. The first sampling signals SA_OUT_1, SA_OUTB_1 sampled in the first sampler 130_1 may be fed back to the 1_2 equalization circuit 150_2.

The second sampler 130_2 may sample a second summer output signal SUM_OUT_2, SUM_OUTB_2 according to a second clock signal CLK2 to generate second sampling signals SA_OUT_2, SA_OUTB_2. Specifically, the second sampling circuit 140_2 may sample the second summer output signal SUM_OUT_2, SUM_OUTB_2 in synchronization with the second clock signal CLK2. In addition, the 1_2 equalization circuit 150_2 may equalize the second sampling signals SA_OUT_2, SA_OUTB_2 in synchronization with the second clock signal CLK2. The 1_2 equalization circuit 150_2 may apply an equalization coefficient acquired based on a difference between the first bias voltage BIAS_1 and the second bias voltage BIAS_2 so as to equalize the second sampling signals SA_OUT_2, SA_OUTB_2. The second sampling signals SA_OUT_2, SA_OUTB_2 sampled in the second sampler 130_2 may be fed back to the 1_3 equalization circuit 150_3.

The third sampler 130_3 may sample the first summer output signal SUM_OUT_1, SUM_OUTB_1 according to a third clock signal CLK3 to generate third sampling signals SA_OUT_3, SA_OUTB_3. Specifically, the third sampling circuit 140_3 may sample the first summer output signal SUM_OUT_1, SUM_OUTB_1 in synchronization with the third clock signal CLK3. In addition, the 1_3 equalization circuit 150_3 may equalize the third sampling signals SA_OUT_3, SA_OUTB_3 in synchronization with the third clock signal CLK3. The 1_3 equalization circuit 150_3 may apply an equalization coefficient acquired based on a difference between the first bias voltage BIAS_1 and the second bias voltage BIAS_2 so as to equalize the third sampling signals SA_OUT_3, SA_OUTB_3. The third sampling signals SA_OUT_3, SA_OUTB_3 sampled in the third sampler 130_3 may be fed back to the 1_4 equalization circuit 150_4.

The fourth sampler 130_4 may sample the second summer output signal SUM_OUT_2, SUM_OUTB_2 according to a fourth clock signal CLK4 to generate fourth sampling signals SA_OUT_4, SA_OUTB_4. Specifically, the fourth sampling circuit 140_4 may sample the second summer output signal SUM_OUT_2, SUM_OUTB_2 in synchronization with the fourth clock signal CLK4. In addition, the 1_4 equalization circuit 150_4 may equalize the fourth sampling signals SA_OUT_4, SA_OUTB_4 in synchronization with the fourth clock signal CLK4. The 1_4 equalization circuit 150_4 may apply an equalization coefficient acquired based on a difference between the first bias voltage BIAS_1 and the second bias voltage BIAS_2 so as to equalize the fourth sampling signals SA_OUT_4, SA_OUTB_4. The fourth sampling signals SA_OUT_4, SA_OUTB_4 sampled in the fourth sampler 130_4 may be fed back to the 1_1 equalization circuit 150_1.

In some implementations, while the calibration operation according to the present disclosure is performed, voltage levels of the bias voltages BIAS_1, BIAS_2 may be kept equal. Hence, the influence of the equalization coefficient, set based on the difference between the first bias voltage BIAS_1 and the second bias voltage BIAS_2, on sampling of the first to fourth sampling signals may be minimized.

The first clock signal CLK1, the second clock signal CLK2, the third clock signal CLK3, and the fourth clock signal CLK4 may each have a 90-degree phase difference, having the same frequency while generating signals at different time points. For example, if the first clock signal CLK1 is a reference clock signal, the second clock signal CLK2 may have a phase delayed by 90 degrees relative to the first clock signal CLK1. Furthermore, the third clock signal CLK3 may have a 180-degree phase difference relative to the first clock signal CLK1 and a phase delayed by 90 degrees relative to the second clock signal CLK2. Similarly, the fourth clock signal CLK4 may have a 180-degree phase difference relative to the second clock signal CLK2 and a phase delayed by 90 degrees relative to the third clock signal CLK3.

In some implementations, the receive circuit (for example, 100 in FIG. 3) according to the present disclosure may further include a first latch circuit 170_1, a second latch circuit 170_2, a third latch circuit 170_3, and a fourth latch circuit 170_4. Each of the first to fourth latch circuits 170_1-170_4 may receive each of the first to fourth sampling signals SA_OUT_1-SA_OUT_4, SA_OUTB_1-SA_OUTB_4 and generate and output first to fourth offset signals OFFSET_OUT_1-OFFSET_OUT_4, respectively. The first to fourth offset signals OFFSET_OUT_1-OFFSET_OUT_4 may be transmitted to the control logic circuit 200.

In some implementations, the receive circuit may be configured to output signals without passing through latch circuits 170_1-170_4. Therefore, for convenience of explanation, the term “sampling signal (SA_OUT, SA_OUTB)” or “offset signal (OFFSET_OUT)” may be used interchangeably as a term referring to a signal output from the receive circuit and provided to the control logic circuit.

Referring to FIGS. 5 and 7, in an exemplary implementation, the receive circuit 100 includes four samplers, each of which may form two feedback paths depending on the state of the feedback sampling signals SA_FID, SA_FIDB that are provided. For example, each sampler may form two feedback paths, namely a feedback path activated when the feedback sampling signal SA_FID is at a high level and another feedback path activated when the feedback sampling signal SA_FIDB is at a high level. Therefore, in the illustrated implementation, an offset calibration operation may be performed for eight feedback paths in total. However, the scope of the present disclosure is not limited to this, and the number of feedback paths may vary depending on design.

In some implementations, the control logic circuit 200 may be configured to control the first summer output signal SUM_OUT to a high level so as to control at least one of the first sampling signal or the third sampling signal to a high level, thereby controlling a feedback sampling signal provided to at least one of the 1_2 equalization circuit 150_2 or the 1_4 equalization circuit 150_4 to a high level, and thus generate an offset compensation signal associated with at least one of the second sampling circuit 140_2 and the 1_2 equalization circuit 150_2 or the fourth sampling circuit 140_4 and the 1_4 equalization circuit 150_4. Likewise, the control logic circuit 200 may be configured to control the second summer output signal SUM_OUT to a high level so as to control at least one of the second sampling signal or the fourth sampling signal to a high level, thereby controlling a feedback sampling signal provided to at least one of the 1_3 equalization circuit 150_3 or the 1_1 equalization circuit 150_1 to a high level, and thus generate an offset compensation signal associated with at least one of the third sampling circuit 140_3 and the 1_3 equalization circuit 150_3 or the first sampling circuit 140_1 and the 1_1 equalization circuit 150_1. In accordance with the above description, cases in which the control logic circuit 200 controls the first or second summer output signal SUM_OUT to a low level are also to be understood.

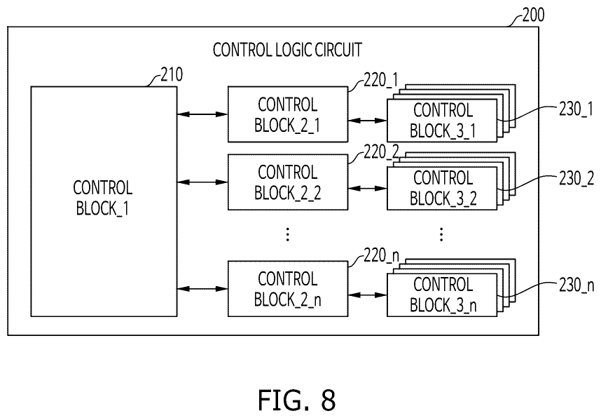

FIG. 8 is a diagram for explaining a control logic circuit according to some implementations of the present disclosure. In FIG. 8 and below, internal configurations of the control logic circuit 200 are described by separating them according to function for convenience of explanation, but this does not necessarily mean that the internal configurations of the control logic circuit 200 are physically separated.

Referring to FIG. 8, the control logic circuit 200 may include a first control block 210, a plurality of second control blocks 220_1, 220_2, . . . , 220_n, and a plurality of third control blocks 230_1, 230_2, . . . , 230_n.

The first control block 210 may be configured to perform overall management and control of the entire calibration operation. The first control block 210 may initiate and terminate the calibration operation and may monitor the system state to determine an appropriate time to operate. In some implementations, if the receive circuit is implemented in a memory device, the first control block 210 may receive a device reset signal from a memory controller and determine whether to execute the calibration operation based on that signal.

Also, the first control block 210 may exchange signals with a plurality of second control blocks 220, coordinating so that calibration operations managed by each second control block 220 are performed in parallel. Through this, the entire calibration process may proceed efficiently.

The second control block 220 may receive a signal from the first control block 210 indicating the start of the calibration operation and, based on that signal, may exchange signals with a plurality of third control blocks 230 and perform the calibration operation. For example, the 2_1 control block 220_1 may communicate with the plurality of 3_1 control blocks 230_1 to perform a calibration operation, and the 2_2 control block 220_2 may communicate with the plurality of 3_2 control blocks 230_2 to perform a calibration operation. Thus, each hierarchical control block may operate independently while the overall calibration process proceeds efficiently. Hereinafter, an example is described in which one second control block 220 manages the operations of four third control blocks 230, but the scope of the present disclosure is not limited thereto.

Upon completion of the calibration operation, each of the plurality of second control blocks 220_1, 220_2, . . . , 220_n may transmit a completion signal to the first control block 210.

The third control block 230 may receive information about which feedback path is to be calibrated from the second control block 220. Based on that information, the third control block 230 may control components in the receive circuit so as to acquire a sampling signal according to that feedback path. For example, the third control block 230 may send control signals to constituents of the receive circuit, such as a sampler, an equalization circuit, or a summer, to set a signal path for calibration and enable the sampling operation. The third control block 230 may also transmit the obtained sampling signal to the second control block 220, receive a calibration code from the second control block 220, and update the receive circuit accordingly. For example, by applying the received calibration code to components of the receive circuit such as the equalization circuit, the third control block 230 may correct the voltage offset according to the characteristics of the feedback path.

In FIG. 8, the first control block 210 and the third control block 230 are illustrated as unconnected, but it is not limited to this, and the first control block 210 and the third control block 230 can exchange signals for calibration operations.

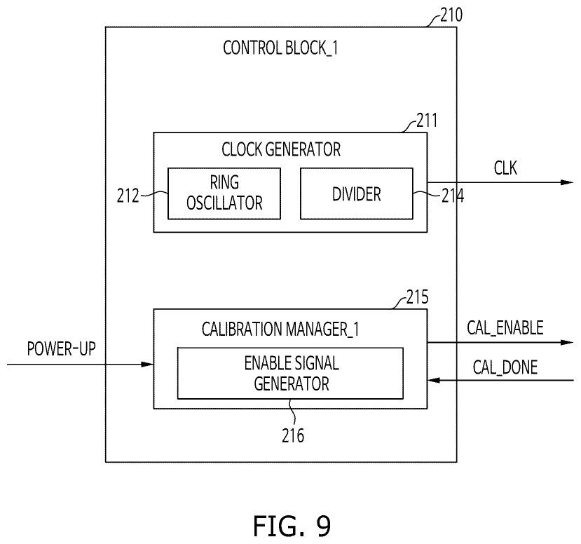

FIG. 9 is a diagram for explaining a first control block according to some implementations of the present disclosure.

Referring to FIG. 9, the first control block 210 may include a clock generator 211 configured to generate a clock signal CLK, and a first calibration manager 215 configured to generate an enable signal CAL_ENABLE.

The clock generator 211 may include a ring oscillator 212 and a frequency divider 214, and it may generate the clock signal CLK required for a calibration operation. The clock generator 211 may respond to activation of the enable signal CAL_ENABLE by the first calibration manager 215 by producing the clock signal CLK.

The ring oscillator 212 may, for example, generate an oscillator signal (OSC signal) and may include an inverter chain of multiple inverters. Each inverter may accept the output of the preceding inverter as input, passing the signal sequentially, thus forming a feedback structure that generates a periodic oscillator signal. The ring oscillator 212, however, is not limited to that structure and may generate signals in various ways. The ring oscillator 212 may provide a fundamental signal needed for the calibration operation.

The frequency divider 214 may reduce the frequency of the oscillator signal generated by the ring oscillator 212. Through this, a clock signal CLK at a frequency appropriate for the calibration operation may be generated. In some implementations, the frequency divider 214 may also introduce a phase shift to generate multiple clock signals having a 90-degree phase difference.

The clock generator 211 may then transmit the clock signal CLK for calibration to one or both of the second control block 220 and the third control block 230.

The first calibration manager 215 may govern initiation and termination of the calibration operation. The first calibration manager 215 may receive a power-up signal POWER-UP and may determine when to start the calibration operation based on that signal. In other words, upon an initial operation or power-up operation, the receive circuit may automatically perform offset calibration. For example, if the receive circuit of the present disclosure is implemented within a memory device, the first calibration manager 215 may receive a power-up signal POWER-UP. The power-up signal POWER-UP may be an internally generated signal that arises when the memory device powers up. Once the calibration operation starts, the first calibration manager 215 may activate the enable signal CAL_ENABLE and transmit it to lower modules such as the clock generator 211 and the second control block 220.

The enable signal CAL_ENABLE may be generated by an enable signal generator 216. Also, the first calibration manager 215 may receive a completion signal CAL_DONE from the second control block 220 representing that the calibration operation is completed. Upon receiving the completion signal CAL_DONE, the first calibration manager 215 may deactivate (e.g., drive low) the enable signal CAL_ENABLE, ending the calibration operation.

Depending on the implementation, the first calibration manager 215 may manage multiple second control blocks 220. In this case, the first calibration manager 215 may receive a completion signal CAL_DONE individually from each second control block 220. The first calibration manager 215 may deactivate the enable signal CAL_ENABLE once it has received the completion signals CAL_DONE from all second control blocks 220.

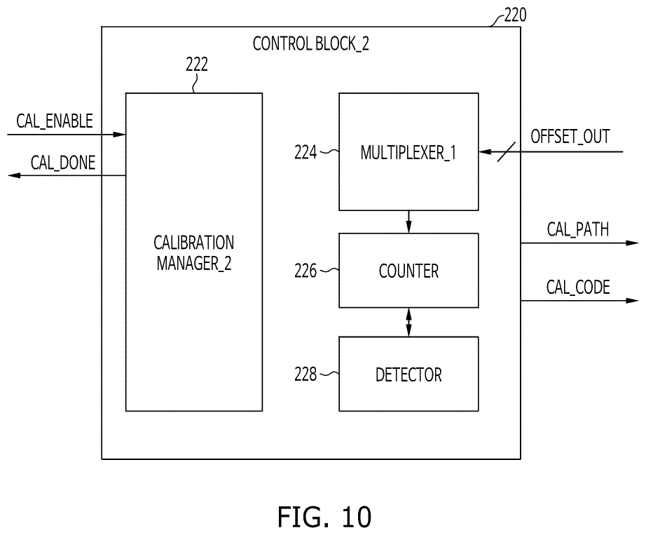

FIG. 10 is a diagram for explaining a second control block according to some implementations of the present disclosure.

Referring to FIG. 10, the second control block 220 may receive the enable signal CAL_ENABLE from the first control block 210 and may exchange signals with multiple third control blocks 230 to perform a calibration operation. When the calibration operation finishes, the second control block 220 may send the completion signal CAL_DONE to the first control block 210 to indicate that the calibration has ended.

The second control block 220 may include a second calibration manager 222, a first multiplexer 224, a counter 226, and a detector 228.

The second calibration manager 222 may receive the enable signal CAL_ENABLE to serve as the central controller for the calibration operation. In some implementations, once CAL_ENABLE transitions high, the second calibration manager 222 may interact with multiple third control blocks 230 so that each third control block carries out its calibration in sequence.

For example, each third control block 230 may control the receive circuit for data signals that have eight feedback paths. The second calibration manager 222 may sequentially control multiple third control blocks 230 so that calibration operations for each feedback path are carried out. Specifically, the second calibration manager 222 may send a path signal CAL_PATH to third control blocks 230_1, 230_2, . . . , 230_n (where n≥3) in order, so that each third control block calibrates a certain feedback path. In an implementation where one second control block 220 manages the operations of four third control blocks 230, the second calibration manager 222 may control the third control blocks 230_1, 230_2, 230_3, and 230_4 in sequence so that calibration operations are performed on eight feedback paths. Consequently, a total of 32 feedback paths could undergo calibration. However, this is only an example and does not limit the scope of the present disclosure.

Through such coordination, calibration for multiple feedback paths may be carried out systematically. Note that the number of feedback paths is merely exemplary and the scope of the present disclosure is not limited thereto.

Depending on the implementation, the path signal CAL_PATH may have multiple bits for effectively indicating the feedback path. For instance, if there are eight feedback paths, CAL_PATH may be 3 bits. However, the bit width of CAL_PATH may vary depending on the implementation.

In some implementations, calibration for each feedback path may be performed over a defined number of clock cycles. The calibration process for each feedback path may include an up/down counting operation of the counter 226, described below. The second calibration manager 222 may monitor whether the defined number of cycles has ended. If it has ended, the second calibration manager 222 may generate or send an offset compensation signal CAL_CODE concerning the corresponding feedback path to the third control block 230. Alternatively, the third control block 230 may monitor the end of the defined period based on the clock signal and transmit a signal to notify the second calibration manager 222 each time the calibration operation for one feedback path is completed. Furthermore, if the period for a specific feedback path has ended, the second calibration manager 222 may update the path signal CAL_PATH so that calibration operations for the next feedback path can be performed.

In some implementations, if the receive circuit of the present disclosure is implemented in a memory device, each third control block 230 may correspond to a data line to handle calibration for that line. In one implementation, if there are eight data lines in the memory device, two second control blocks could each manage four third control blocks to handle calibration operations.

The first multiplexer 224 may receive offset signals OFFSET_OUT from multiple third control blocks 230, each offset signal corresponding to one feedback path. The first multiplexer 224 may select the offset signal from the feedback path currently being calibrated and pass it to the counter 226. The first multiplexer 224 may decide which feedback path is being calibrated based on the path signal CAL_PATH received from the second calibration manager 222. Through this, the second control block 220 may interact with multiple third control blocks 230 and perform sequential calibration on multiple feedback paths.

The counter 226 may generate and adjust a count value used to determine an offset compensation signal CAL_CODE. The counter 226 may receive the offset signal and increment or decrement its count value depending on the offset signal's state (e.g., 0 or 1). For instance, if the offset signal is 1, the count might be incremented, and if it is 0, the count might be decremented.

Depending on the implementation, the count value may be K bits (K being a natural number). The upper L bits (L a natural number) of those K bits may be used to determine the offset compensation signal CAL_CODE, while the lower (K-L) bits may be used for gain control. The generated offset compensation signal CAL_CODE may be sent back to the third control block 230 and then may be stored in the receive circuit. Alternatively, the offset compensation signal CAL_CODE may be further decoded by at least one of the second control block 220 or the third control block 230 before being stored in the receive circuit.

If no voltage offset arises from subtle mismatch among elements in a given feedback path, the count value generated by the counter 226 may fluctuate up and down around its initial state. On the other hand, if a voltage offset does exist due to subtle mismatch among elements in a particular feedback path, the count may deviate from the initial value and may be biased in a particular direction. The deviation of the count value thus indicates the presence of a voltage offset, and a calibration operation may generate an offset compensation signal CAL_CODE to compensate for that offset.

Additionally, the counter 226 may reset its count value upon the completion of calibration for each feedback path.

The detector 228 may ensure that the count value, which increments or decrements in the counter 226, does not surpass a preset upper or lower threshold. If the count reaches the upper threshold, further increments may be restricted, and if it reaches the lower threshold, further decrements may be restricted. This prevents abnormal fluctuations in the count value during the calibration operation.

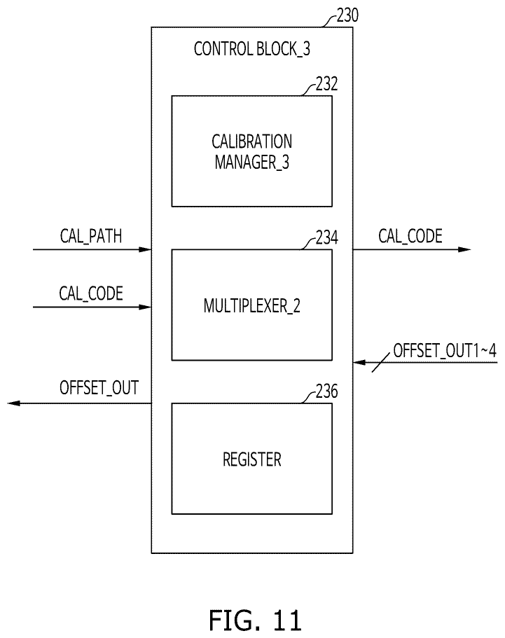

FIG. 11 is a diagram for explaining a third control block according to some implementations of the present disclosure.

Referring to FIG. 11, the third control block 230 may receive a path signal CAL_PATH and an offset compensation signal CAL_CODE from the second control block 220 and, based on these, may acquire an offset signal OFFSET_OUT1-4 for a particular feedback path or store and update the offset compensation signal CAL_CODE in the receive circuit.

The third control block 230 may include a third calibration manager 232, a second multiplexer 234, and a register 236.

The third calibration manager 232 may receive the path signal CAL_PATH from the second control block 220. Based on the signal, the third calibration manager 232 may control a specific feedback path to acquire offset signals OFFSET_OUT1-4. The third calibration manager 232 may adjust the voltage levels input to the components of the receive circuit or control operations so that an offset signal OFFSET_OUT1-4 is obtained through the desired feedback path. The acquired offset signal OFFSET_OUT (e.g., some or all of-FSET_OUT1-4) may be input to the second multiplexer 234.

The second multiplexer 234 may select from among offset signals of multiple feedback paths and output the offset signal corresponding to the currently target path for calibration. The selected offset signal is provided to the second control block 220, where the counter 226 may adjust its count to generate the offset compensation signal CAL_CODE.

The register 236 may receive the offset compensation signal CAL_CODE from the second control block 220 and store or update it in a component of the receive circuit associated with that particular feedback path. Consequently, when receiving data signals, the receive circuit may compensate for voltage offsets that arise from mismatch between paired elements in the feedback path. Ultimately, data-signal determination accuracy and data-processing efficiency may be enhanced.

In some implementations, the third calibration manager 232 may check the level (e.g., high or low) of signals received from the second control block 220 to determine whether the third control block 230 is currently targeted for calibration. For example, if the received signal is high, that may indicate that calibration is targeted, and the third calibration manager 232 may control the register 236 to store or update the offset compensation signal CAL_CODE. Conversely, if the received signal is low, that may indicate that calibration is not targeted, and the third calibration manager 232 may maintain the register 236 state.

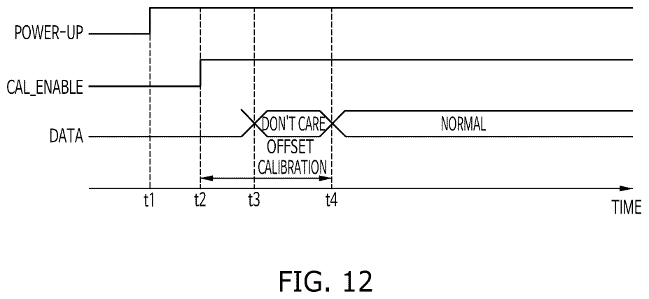

FIG. 12 is a timing diagram showing an initial operation of a receiver according to some implementations of the present disclosure.

Referring to FIG. 12, the receiver may be powered on and carry out an offset calibration operation in an initial operation. Depending on the implementation, the initial operation may be called a power-up operation or a power-on reset (POR) operation.

The receiver may be powered on at a first time t1. At a second time t2, an enable signal CAL_ENABLE may transition from low to high. Starting at t2, the receiver may perform an offset calibration operation. In other words, during an initial or power-up operation, the receiver may automatically perform offset calibration.

Starting from a third time t3, the receiver may receive data via a data signal DATA. The data received from t3 to a fourth time t4 may be data for stabilizing the receiver. That is, the data received from t3 to t4 may be meaningless as actual data. Therefore, the interval from t3 to t4 may be called a “don't-care” interval.

Once the don't-care interval ends, from the fourth time t4 onward, the receiver may receive meaningful data containing information to be transmitted. That is, the receiver may begin normal operation at t4. The fourth time t4 may be when offset calibration completes. In other words, the offset calibration operation may take place between t2 and t4.

In this disclosure, the offset calibration operation may encompass a series of processes to detect a voltage offset arising in the receive circuit and compensate it by storing or updating calibration codes. Specifically, the calibration operation may include setting a particular feedback path, adjusting voltages so that a sampling signal is acquired through that path, and then, based on the acquired sampling signal, incrementing or decrementing a counter, which subsequently generates and stores a calibration code. As described above, FIG. 12's timing diagram may depict how a receiver uses the time from power-up until normal operation to carry out offset calibration.

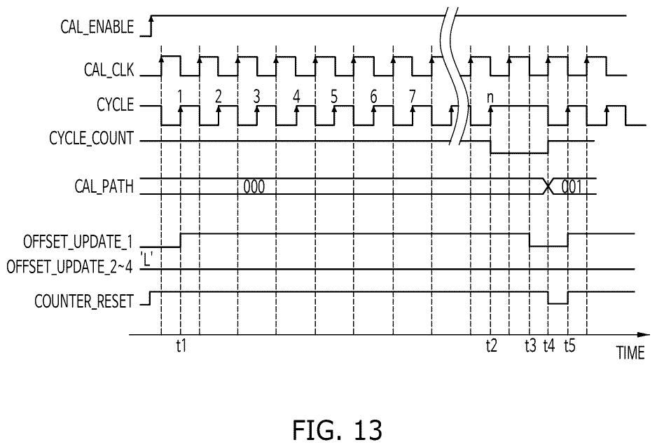

FIG. 13 is a diagram for explaining an offset calibration operation according to some implementations of the present disclosure.

Referring to FIG. 13, the offset calibration operation may begin when an enable signal CAL_ENABLE transitions from low to high. The enable signal CAL_ENABLE may be generated by the first control block and transmitted to a lower module (e.g., the second control block and the third control block).

A calibration clock signal CAL_CLK may then be generated. The calibration clock signal CAL_CLK may operate at a regular interval for each cycle and serve as a synchronization signal for generating offset signals in the receive circuit.

A cycle signal CYCLE may operate at the same interval as the calibration clock signal CAL_CLK and may be controlled based on a cycle count signal CYCLE_COUNT. For example, the cycle count signal CYCLE_COUNT may track the repetition of the cycle signal CYCLE, and once a set count n is reached, it may transition to a low level. This may pause the cycle signal CYCLE, at which point the calibration operation may move on to the next feedback path. One cycle may correspond to the time needed to complete calibration of a particular feedback path.

At a first time t1, a first update signal OFFSET_UPDATE_1 may transition high, and the third control block associated with OFFSET_UPDATE_1 may then perform calibration. While OFFSET_UPDATE_1 is active, among the multiple third control blocks managed by the second control block, only that third control block associated with OFFSET_UPDATE_1 carries out calibration. During that time, the second through fourth update signals OFFSET_UPDATE_2-4 may remain inactive (low). Therefore, third control blocks associated with OFFSET_UPDATE_2-4 do not calibrate during that interval.

For convenience, the third control block associated with the first update signal (OFFSET_UPDATE_1) is denoted as the 3_1 control block, the third control block associated with the second update signal (OFFSET_UPDATE_2) is denoted as the 3_2 control block, the third control block associated with the third update signal (OFFSET_UPDATE_3) is denoted as the 3_3 control block, and the third control block associated with the fourth update signal (OFFSET_UPDATE_4) is denoted as the 3_4 control block.

Also, at a second time t2, the cycle count signal CYCLE_COUNT may switch to a low level once the cycle signal CYCLE has repeated the predetermined number of times n. This may indicate that calibration for a specific feedback path is completed. In that case, the cycle signal CYCLE may no longer toggle and may remain in a high level state.

At a third time t3, the first update signal OFFSET_UPDATE_1 may be deactivated, and at a fifth time t5, it may be reactivated. During this process, the path signal CAL_PATH may be changed to indicate the next feedback path. Consequently, the 3_1 control block may proceed with calibration of the next feedback path.

Additionally, while the feedback path changes, a counter reset signal COUNTER_RESET may briefly go low. The second control block may respond by resetting the counter to an initial value, preparing for calibration on the next feedback path.

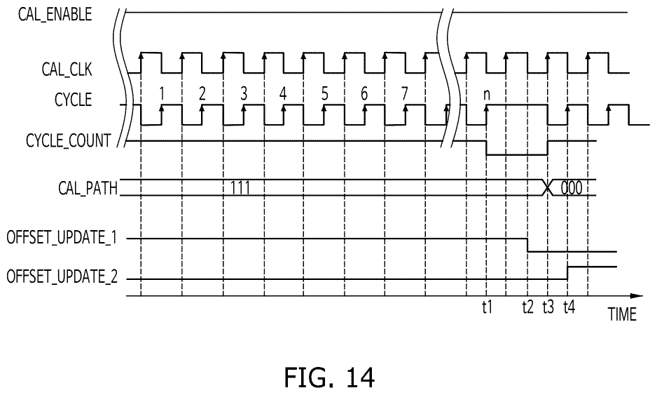

FIG. 14 is a diagram for explaining an offset calibration operation according to some implementations of the present disclosure. Redundant descriptions with FIG. 13 are briefly stated or omitted.

Referring to FIG. 14, the calibration operation may proceed in sequence through changes in the path signal CAL_PATH and the update signal OFFSET_UPDATE.

At a first time t1, the cycle count signal CYCLE_COUNT may go low, causing the cycle signal CYCLE to remain high.

Between a second time t2 and a fourth time t4, CAL_PATH may switch from “111” to “000,” signifying that calibration associated with a particular third control block is finished.

Also, at the second time t2, OFFSET_UPDATE_1 may be deactivated, and at the fourth time t4, OFFSET_UPDATE_2 may be activated. This indicates that calibration for a new feedback path has begun. Therefore, the third_1 control block may end the calibration operation, and subsequently, the third_2 control block may initiate the calibration operation for the new feedback path.

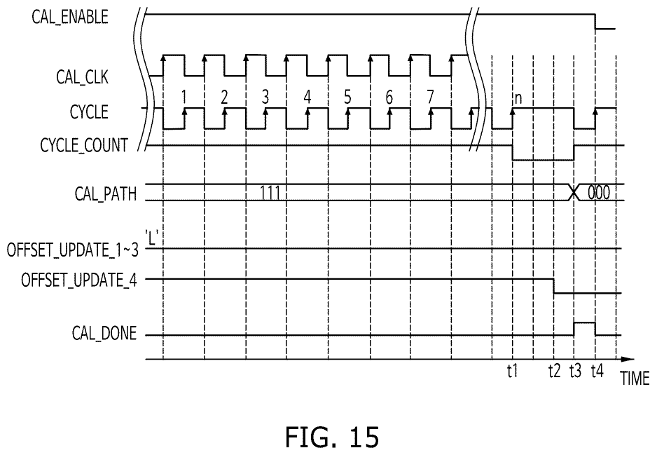

FIG. 15 is a diagram for explaining an offset calibration operation according to some implementations of the present disclosure. Overlapping details with FIGS. 13 and 14 are briefly covered or omitted.

Referring to FIG. 15, at a first time t1, the cycle count signal CYCLE_COUNT may transition low, causing the cycle signal CYCLE to remain high.

Accordingly, at a second time t2, OFFSET_UPDATE_4 may be deactivated. This indicates that all third control blocks have finished calibration.

Therefore, at a third time t3, the second control block may generate a completion signal CAL_DONE, meaning that all calibration operations managed by the second control block have ended. CAL_DONE may be transmitted to the first control block.

At a fourth time t4, the enable signal CAL_ENABLE may go low, ending the calibration operation.

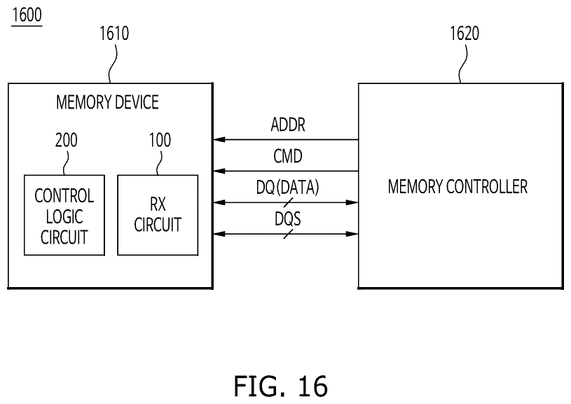

FIG. 16 is a block diagram for explaining a memory system according to some implementations of the present disclosure. Referring to FIG. 16, a memory system 1600 may include a memory device 1610 and a memory controller 1620.

The memory controller 1620 may write data DATA to the memory device 1610 or read out data DATA stored in the memory device 1610. For example, the memory controller 1620 may generate a command CMD and an address ADDR in order to write or read data DATA. In some implementations, the memory controller 1620 may be at least one of a memory controller, an application processor (AP), a system on chip (SoC), a central processing unit (CPU), a digital signal processor (DSP), or a graphics processing unit (GPU).

The memory device 1610 may store data DATA received through multiple data lines DQ under the control of the memory controller 1620 or, alternatively, transmit data DATA stored in the memory device 1610 to the memory controller 1620 via multiple data lines DQ. The memory device 1610 may transmit data to the memory controller 1620 in synchronization with a data strobe signal provided through a data strobe line DQS. For example, the memory device 1610 and the memory controller 1620 may send and receive data DATA via multiple data lines DQ and a data strobe line DQS.

In some implementations, the memory device 1610 may include dynamic random access memory (DRAM). However, the scope of the present disclosure is not limited, and the memory device 1610 may include one or more of SRAM, SDRAM, ROM, PROM, EPROM, EEPROM, flash memory, PRAM, MRAM, RRAM, FRAM, etc.

For example, the memory device (1610) and memory controller (1620) may communicate using a DDR (Double Data Rate) interface. However, the scope of the present disclosure is not limited thereto. For instance, the memory device (1610) and memory controller (1620) may communicate based on at least one of various interfaces such as USB (Universal Serial Bus), MMC (multimedia card), PCI (Peripheral Component Interconnection), PCI-E (PCI-express), ATA (Advanced Technology Attachment), SATA (Serial-ATA), PATA (Parallel-ATA), SCSI (small computer system interface), ESDI (enhanced small disk interface), IDE (Integrated Drive Electronics), MIPI (Mobile Industry Processor Interface), NVM-e (Nonvolatile Memory-express), or NAND interface.

In some implementations, the memory device 1610 may include a receive circuit 100 and a control logic circuit 200. The receive circuit 100 may perform an offset calibration operation for multiple feedback paths, and the control logic circuit 200 may control the receive circuit 100's offset calibration operation by comprehensively controlling the receive circuit 100. For example, when the memory device 1610 is in an initial state after power-up, the receive circuit 100 and the control logic circuit 200 may perform the offset calibration described above. Subsequently, if the memory device 1610 receives data DATA from the memory controller 1620, the receive circuit 100 may remove voltage offsets based on offset compensation codes. The receive circuit 100 and the control logic circuit 200 according to the present disclosure are further detailed with reference to FIGS. 1-15.

As described, since the first equalization circuit structure of the receive circuit 100 is integrated into the sampler, the sampler output signal generated in the previous phase domain may be directly provided to the first equalization circuit structure of the next phase domain. This shortens the feedback path, maintaining feedback time within 1 UI. Through such a configuration, the receive circuit 100 may eliminate noise and intersymbol interference more quickly in the current data signal based on the current clock signal. Hence, the receive circuit 100 may handle high-speed data transmission in a stable and reliable manner, contributing to improved data exchange reliability between the memory device 1610 and the memory controller 1620 in a high-speed interface environment.

Examples of the present disclosure have been described based on the receive circuit 100 in the memory device 1610 (i.e., the implementation of FIG. 16). For example, the configurations of the memory device 1610 and the memory controller 1620 described above are exemplary only, and the scope of the present disclosure is not so limited. The receive circuit 100 of the present disclosure may be applied to various signal transmitters, signal receivers, or various electronic devices configured to send and receive information through signal lines. Moreover, the receive circuit 100 of the present disclosure may be used not only for data lines or data signals but also for various signals being received or transmitted.

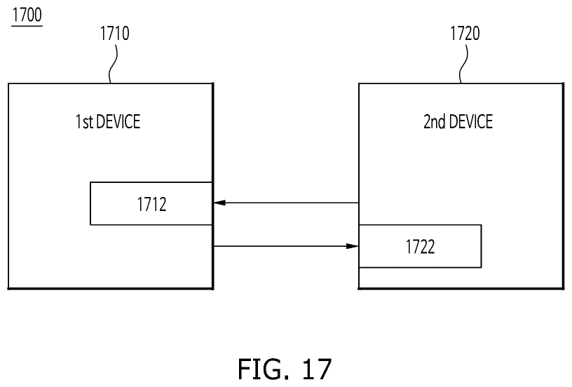

FIG. 17 is a block diagram illustrating an example of an electronic device having a receive circuit according to some implementations of the present disclosure.

Referring to FIG. 17, a system 1700 may include a first device 1710 and a second device 1720. Each of the first device 1710 and the second device 1720 may exchange information signals, such as data signals, electrical signals, analog signals, or digital signals, within the system 1700. For example, each of the first device 1710 and the second device 1720 may be an information-processing device such as a signal transmitter, a signal receiver, an IP block, an electronic module, or an electronic circuit.

Each of the first device 1710 and the second device 1720 may include a receive circuit 1712, 1722. Each receive circuit 1712, 1722 may be the receive circuit described with reference to FIGS. 1 to 15. That is, each receive circuit 1712, 1722 may be configured to filter noise from signals received by the first device 1710 or the second device 1720. Additionally, at initial or power-up operations, each of the first device 1710 or the second device 1720 may perform the offset calibration operation with reference to FIGS. 1 to 15.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The exemplary implementations of the present disclosure described above are presented for illustration only. Those skilled in the art will appreciate that various modifications, changes, and additions can be made without departing from the spirit and scope of the present disclosure, and such modifications, changes, and additions should be understood to be encompassed within the scope of the appended claims.

Those skilled in the art will also appreciate that many substitutions, alterations, and changes may be made without departing from the technical spirit of the present disclosure, so the present disclosure is not restricted by the foregoing implementations and accompanying drawings.

What is claimed is:

1. A memory device comprising:
a buffer configured to compare a data signal to a reference voltage and generate an amplified signal;
a summer configured to generate a summer output signal based on the amplified signal; and
a sampler comprising (i) a sampling circuit configured to sample the summer output signal based on a clock signal and generate a sampling signal, and (ii) a first equalization circuit structure connected to the sampling circuit and configured to equalize the sampling signal based on a feedback sampling signal, wherein the sampling circuit is configured to generate the feedback sampling signal prior to the sampling signal,
wherein the first equalization circuit structure comprises:
a first transistor configured to receive the feedback sampling signal;
a second transistor structure between the first transistor and the sampling circuit and configured to receive a bias voltage, the bias voltage being associated with an equalization coefficient; and
a third transistor structure between the first transistor and the sampling circuit and configured to receive an offset compensation signal for the sampler.

2. The memory device of claim 1, wherein the first transistor is configured to receive the feedback sampling signal through a gate of the first transistor, and
wherein the second transistor structure comprises:
a second transistor connected to the first transistor and a first node of the sampling circuit; and
a third transistor connected to the first transistor and a second node of the sampling circuit.

3. The memory device of claim 2, wherein the third transistor structure comprises:
a fourth transistor connected between the first transistor and the first node of the sampling circuit; and
a fifth transistor connected between the first transistor and the second node of the sampling circuit.

4. The memory device of claim 3, wherein the fourth transistor is configured to receive a first offset compensation signal through a gate of the fourth transistor,
wherein the fifth transistor is configured to receive a second offset compensation signal through a gate of the fifth transistor, and
wherein the first offset compensation signal and the second offset compensation signal are associated with a voltage offset difference between the second transistor and the third transistor.

5. The memory device of claim 3, wherein the first equalization circuit structure comprises a fourth transistor structure connected in series with the third transistor structure, and
wherein the fourth transistor structure comprises:
a sixth transistor connected to the fourth transistor and configured to receive the feedback sampling signal through a gate of the sixth transistor; and
a seventh transistor connected to the fifth transistor and configured to receive the feedback sampling signal through a gate of the seventh transistor.

6. The memory device of claim 1, wherein the third transistor structure comprises a plurality of third sub-transistors, and
a number of the plurality of third sub-transistors corresponds to a bit number of the offset compensation signal.

7. The memory device of claim 1, comprising a control logic circuit configured to determine the offset compensation signal and transmit the offset compensation signal to a gate of the third transistor structure.

8. The memory device of claim 7, wherein the control logic circuit is configured to transmit a first control signal to the buffer, and
wherein the buffer is configured to, based on the first control signal, output a supply voltage as the amplified signal.

9. The memory device of claim 8, comprising a second equalization circuit structure connected to the summer,
wherein the control logic circuit is configured to transmit a second control signal to the second equalization circuit structure, and
wherein the second equalization circuit structure is configured to, based on the second control signal, output the summer output signal at a predetermined value so that the feedback sampling signal has a first logic level.

10. The memory device of claim 9, wherein the second transistor structure comprises:
a second transistor connected to the first transistor and a first node of the sampling circuit, the second transistor being configured to receive a first bias voltage through a gate of the second transistor; and
a third transistor connected to the first transistor and a second node of the sampling circuit, the third transistor being configured to receive a second bias voltage through a gate of the third transistor,
based on the control logic circuit transmitting the first control signal and the second control signal, the first bias voltage is equal to the second bias voltage.

11. The memory device of claim 7, wherein the control logic circuit comprises:
a clock generator configured to generate the clock signal; and
a calibration manager configured to generate an enable signal instructing a calibration operation on the sampler.

12. The memory device of claim 11, wherein the calibration manager is configured to receive a power-up signal and activate, based on the power-up signal, the enable signal.

13. The memory device of claim 7, wherein the clock signal comprises first to fourth clock signals each having a 90-degree phase difference,
wherein the summer comprises a first summer configured to generate a first summer output signal and a second summer configured to generate a second summer output signal, and
wherein the sampling circuit comprises:
a first sampling circuit configured to sample the first summer output signal based on the first clock signal and generate a first sampling signal;
a second sampling circuit configured to sample the second summer output signal based on the second clock signal and generate a second sampling signal;
a third sampling circuit configured to sample the first summer output signal based on the third clock signal and generate a third sampling signal; and
a fourth sampling circuit configured to sample the second summer output signal based on the fourth clock signal and generate a fourth sampling signal.

14. The memory device of claim 13, wherein the sampling circuit comprises a plurality of feedback paths corresponding to the first to fourth sampling circuits, and
wherein the control logic circuit comprises:
a multiplexer configured to select an offset signal for a corresponding feedback path of the plurality of feedback paths;
a counter configured to generate a count value for the selected offset signal; and
a register configured to store the count value.

15. The memory device of claim 13, wherein the first equalization circuit structure comprises:
a first equalization circuit connected to the first sampling circuit and configured to equalize the first sampling signal;
a second equalization circuit connected to the second sampling circuit and configured to equalize the second sampling signal based on the first sampling signal;
a third equalization circuit connected to the third sampling circuit and configured to equalize the third sampling signal based on the second sampling signal; and
a fourth equalization circuit connected to the fourth sampling circuit and configured to equalize the fourth sampling signal based on the third sampling signal.

16. The memory device of claim 15, wherein the control logic circuit is configured to:
drive the first summer output signal so that at least one of the first sampling signal or the third sampling signal is at a high level; and
generate the offset compensation signal associated with at least one of (i) the second sampling circuit and the second equalization circuit or (ii) the fourth sampling circuit and the fourth equalization circuit.

17. The memory device of claim 1, wherein the first equalization circuit structure is configured to adjust a voltage level of a node connected to the sampling circuit based on the offset compensation signal.

18. A memory device, comprising:
a receive circuit configured to process a data signal from a memory controller and generate output data; and
a control logic circuit configured to control the receive circuit and generate an offset compensation signal for the receive circuit,
wherein the receive circuit comprises:
a buffer configured to compare the data signal to a reference voltage and generate an amplified signal;
a summer configured to generate a summer output signal based on the amplified signal; and
a sampler comprising (i) a sampling circuit configured to sample the summer output signal based on a clock signal and generate a sampling signal, and (ii) a first equalization circuit structure connected to the sampling circuit and configured to equalize the sampling signal based on a feedback sampling signal, wherein the sampling circuit is configured to generate the feedback sampling signal prior to the sampling signal, and
wherein the first equalization circuit structure comprises:
a first transistor configured to receive the feedback sampling signal;
a second transistor structure between the first transistor and the sampling circuit and configured to receive a bias voltage associated with an equalization coefficient; and
a third transistor structure between the first transistor and the sampling circuit and configured to receive the offset compensation signal for the sampler.

19. The memory device of claim 18, wherein the control logic circuit is configured to determine the offset compensation signal, and transmit the offset compensation signal to a gate of the third transistor structure.

20. A memory system, comprising:
a memory device; and
a memory controller configured to write data to the memory device or read data stored in the memory device,
wherein the memory device comprises:
a receive circuit configured to process a data signal from the memory controller and generate output data; and
a control logic circuit configured to control the receive circuit and generate an offset compensation signal for the receive circuit,
wherein the receive circuit comprises:
a buffer configured to compare the data signal to a reference voltage and generate an amplified signal;
a summer configured to generate a summer output signal based on the amplified signal; and
a sampler comprising (i) a sampling circuit configured to sample the summer output signal based on a clock signal and generate a sampling signal, and (ii) a first equalization circuit structure connected to the sampling circuit and configured to equalize the sampling signal based on a feedback sampling signal, wherein the sampling circuit is configured to generate the feedback sampling signal prior to the sampling signal, and
wherein the first equalization circuit structure comprises:
a first transistor configured to receive the feedback sampling signal;
a second transistor structure between the first transistor and the sampling circuit and configured to receive a bias voltage associated with an equalization coefficient; and
a third transistor structure between the first transistor and the sampling circuit and configured to receive the offset compensation signal for the sampler.
